(19) United States
(12) Patent Application Publication
(10) Pub. No.: US 2025/0393242 A1
(43) Pub. Date: Dec. 25, 2025

(54) NITRIDE SEMICONDUCTOR DEVICE AND METHOD OF MANUFACTURING THE SAME

(71) Applicant: FUJI ELECTRIC CO., LTD., Kawasaki-shi (JP)

(72) Inventors: Tsurugi KONDO, Tokyo (JP); Katsunori UENO, Matsumoto-city (JP)

(73) Assignee: FUJI ELECTRIC CO., LTD., Kawasaki-shi (JP)

(21) Appl. No.: 19/192,489

(22) Filed: Apr. 29, 2025

(30) Foreign Application Priority Data
Jun. 20, 2024 (JP) 2024-099737
Dec. 24, 2024 (JP) 2024-227367

(51) Int. Cl. H10D 30/66; H10D 30/01; H10D 62/10; H10D 62/60; H10D 62/85; H10D 62/852; H10D 62/854; H10D 64/68

(52) U.S. Cl. CPC H10D 30/668; H10D 62/102; H10D 62/124; H10D 62/60; H10D 62/8503; H10D 62/852; H10D 62/854; H10D 64/683; H10D 64/693; H10D 30/0297

(57) ABSTRACT

A nitride semiconductor device includes: a nitride semiconductor layer of a first conductivity-type; a well region of a second conductivity-type provided in the nitride semiconductor layer; and a gate insulating film provided on a first surface side of the nitride semiconductor layer so as to cover the well region. The well region includes a first region to which Al is not doped, and a second region to which Al is doped, the second region being provided on the first region. The second region has an Al concentration distribution in which an Al concentration is highest on a first surface in contact with the gate insulating film and decreases in a continuous or stepwise state from the first surface toward the first region.

### CROSS-REFERENCE TO RELATED APPLICATION

This application claims benefit of priority under 35 USC 119 based on Japanese Patent Applications No. 2024-099737 filed on Jun. 20, 2024 and No. 2024-227367 filed on Dec. 24, 2024, the entire contents of which are incorporated by reference herein.

### BACKGROUND OF THE INVENTION

### 1. Field of the Invention

The present disclosure relates to nitride semiconductor devices and methods of manufacturing the same.

### 2. Description of the Related Art

Conventionally known high-electron-mobility transistors having a hetero structure with a composition of AlxGal-xN/GaN (where 0<X≤1) prepared on substrates have a configuration, as disclosed in JPH11-261051A, in which a film thickness of an AlxGal-xN barrier layer formed on a top surface side of a substrate is set within a range that does not cause lattice relaxation, and a part of or all of the barrier layer has an Al composition that is oriented in a direction perpendicular to the substrate of the barrier layer and modulated in a continuous or stepwise state.

Demand for nitride semiconductor devices has been increased that have high channel mobility to implement a MOSFET with low ON-resistance.

### SUMMARY OF THE INVENTION

In view of the foregoing problems, the present disclosure provides a nitride semiconductor device and a method of manufacturing the same having a configuration capable of achieving a MOSFET having low ON-resistance with high channel mobility.

To solve the problems described above, a nitride semiconductor device according to an aspect of the present disclosure including: a nitride semiconductor layer of a first conductivity-type; a well region of a second conductivity-type provided in the nitride semiconductor layer; and a gate insulating film provided on a first surface side of the nitride semiconductor layer so as to cover the well region. The well region includes a first region to which Al is not doped, and a second region to which Al is doped, the second region being provided on the first region. The second region has an Al concentration distribution in which an Al concentration is highest on a first surface in contact with the gate insulating film and decreases in a continuous or stepwise state from the first surface toward the first region.

A method of manufacturing a nitride semiconductor device according to the aspect of the present disclosure including: forming a well region of a second conductivity-type on a first surface side of a nitride semiconductor layer of a first conductivity-type; and forming a gate insulating film on the first surface side of the nitride semiconductor layer so as to cover the well region. The forming the well region includes forming a first region to which Al is not doped, and forming, on the first region, a second region to which Al is doped. The forming the second region is executed so as to form an Al concentration distribution in the second region in which an Al concentration is highest on a first surface in contact with the gate insulating film and decreases in a continuous or stepwise state from the first surface toward the first region.

### BRIEF DESCRIPTION OF THE DRAWINGS

FIG. 1 is a plan view illustrating a configuration example of a GaN semiconductor device according to Embodiment 1 of the present disclosure;

FIG. 2 is a cross-sectional view taken along line A-A′ in the plan view of FIG. 1;

FIG. 3 is an enlarged cross-sectional view of FIG. 2, illustrating a configuration example of a single vertical MOSFET (a unit structure);

FIG. 4 is a schematic view, as an example (Example) of the embodiment of the present disclosure, illustrating an Al concentration distribution in a depth direction from a top surface of a well region and an electron concentration distribution in the depth direction upon a channel formation;

FIG. 5A is a cross-sectional view sequentially illustrating Method 1 of manufacturing a vertical MOSFET according to Embodiment 1 of the present disclosure;

FIG. 5B is a cross-sectional view sequentially illustrating Method 1 of manufacturing the vertical MOSFET according to Embodiment 1 of the present disclosure;

FIG. 5C is a cross-sectional view sequentially illustrating Method 1 of manufacturing the vertical MOSFET according to Embodiment 1 of the present disclosure;

FIG. 5D is a cross-sectional view sequentially illustrating Method 1 of manufacturing the vertical MOSFET according to Embodiment 1 of the present disclosure;

FIG. 5E is a cross-sectional view sequentially illustrating Method 1 of manufacturing the vertical MOSFET according to Embodiment 1 of the present disclosure;

FIG. 5F is a cross-sectional view sequentially illustrating Method 1 of manufacturing the vertical MOSFET according to Embodiment 1 of the present disclosure;

FIG. 5G is a cross-sectional view sequentially illustrating Method 1 of manufacturing the vertical MOSFET according to Embodiment 1 of the present disclosure;

FIG. 6A is a cross-sectional view sequentially illustrating Method 2 of manufacturing the vertical MOSFET according to Embodiment 1 of the present disclosure;

FIG. 6B is a cross-sectional view sequentially illustrating Method 2 of manufacturing the vertical MOSFET according to Embodiment 1 of the present disclosure;

FIG. 6C is a cross-sectional view sequentially illustrating Method 2 of manufacturing the vertical MOSFET according to Embodiment 1 of the present disclosure;

FIG. 7A is a cross-sectional view sequentially illustrating Method 3 of manufacturing the vertical MOSFET according to Embodiment 1 of the present disclosure;

FIG. 7B is a cross-sectional view sequentially illustrating Method 3 of manufacturing the vertical MOSFET according to Embodiment 1 of the present disclosure;

FIG. 7C is a cross-sectional view sequentially illustrating Method 3 of manufacturing the vertical MOSFET according to Embodiment 1 of the present disclosure;

FIG. 7D is a cross-sectional view sequentially illustrating Method 3 of manufacturing the vertical MOSFET according to Embodiment 1 of the present disclosure;

FIG. 8 is a schematic view, as Comparative Example 1 of the present disclosure, illustrating an Al concentration distribution in a depth direction from a top surface of a well region and an electron concentration distribution in the depth direction upon a channel formation;

FIG. 9 is a graph showing results of experiments executed by the inventors, in which electric field mobility is compared between Example and Comparative Example 2;

FIG. 10 is a graph schematically showing a relation of a difference in lattice constant between AlGaN and GaN in the well region according to Example of the present disclosure;

FIG. 11 is a graph schematically showing a relation of a difference in lattice constant between AlGaN and GaN in the well region according to Comparative Example 1 of the present disclosure;

FIG. 12 is a cross-sectional view illustrating a configuration example of a vertical MOSFET (a unit structure) according to Embodiment 2 of the present disclosure;

FIG. 13 is a cross-sectional view illustrating a method of manufacturing the vertical MOSFET according to Embodiment 2 of the present disclosure;

FIG. 14 is a cross-sectional view illustrating a configuration example of a vertical MOSFET (a unit structure) according to Embodiment 3 of the present disclosure;

FIG. 15A is a cross-sectional view illustrating a method of manufacturing the vertical MOSFET according to Embodiment 3 of the present disclosure;

FIG. 15B is a cross-sectional view illustrating the method of manufacturing the vertical MOSFET according to Embodiment 3 of the present disclosure;

FIG. 15C is a cross-sectional view illustrating the method of manufacturing the vertical MOSFET according to Embodiment 3 of the present disclosure;

FIG. 15D is a cross-sectional view illustrating the method of manufacturing the vertical MOSFET according to Embodiment 3 of the present disclosure;

FIG. 15E is a cross-sectional view illustrating the method of manufacturing the vertical MOSFET according to Embodiment 3 of the present disclosure;

FIG. 15F is a cross-sectional view illustrating the method of manufacturing the vertical MOSFET according to Embodiment 3 of the present disclosure;

FIG. 15G is a cross-sectional view illustrating the method of manufacturing the vertical MOSFET according to Embodiment 3 of the present disclosure;

FIG. 16 is a cross-sectional view illustrating a configuration example of a vertical MOSFET (a unit structure) according to Embodiment 4 of the present disclosure;

FIG. 17 is a cross-sectional view illustrating a method of manufacturing the vertical MOSFET according to Embodiment 4 of the present disclosure;

FIG. 18 is a cross-sectional view illustrating a configuration example of a vertical MOSFET (a unit structure) according to Embodiment 5 of the present disclosure;

FIG. 19 is a view schematically illustrating a vertical MOSFET (Configuration Example 1) according to Embodiment 6 of the present disclosure;

FIG. 20 is a view schematically illustrating a vertical MOSFET (Configuration Example 2) according to Embodiment 6 of the present disclosure;

FIG. 21 is a view schematically illustrating a vertical MOSFET (Configuration Example 3) according to Embodiment 6 of the present disclosure;

FIG. 22A is a cross-sectional view sequentially illustrating Method 1 of manufacturing the vertical MOSFET according to Embodiment 6 of the present disclosure;

FIG. 22B is a cross-sectional view sequentially illustrating Method 1 of manufacturing the vertical MOSFET according to Embodiment 6 of the present disclosure;

FIG. 22C is a cross-sectional view sequentially illustrating Method 1 of manufacturing the vertical MOSFET according to Embodiment 6 of the present disclosure;

FIG. 22D is a cross-sectional view sequentially illustrating Method 1 of manufacturing the vertical MOSFET according to Embodiment 6 of the present disclosure;

FIG. 22E is a cross-sectional view sequentially illustrating Method 1 of manufacturing the vertical MOSFET according to Embodiment 6 of the present disclosure;

FIG. 22F is a cross-sectional view sequentially illustrating Method 1 of manufacturing the vertical MOSFET according to Embodiment 6 of the present disclosure;

FIG. 22G is a cross-sectional view sequentially illustrating Method 1 of manufacturing the vertical MOSFET according to Embodiment 6 of the present disclosure;

FIG. 22H is a cross-sectional view sequentially illustrating Method 1 of manufacturing the vertical MOSFET according to Embodiment 6 of the present disclosure;

FIG. 23A is a cross-sectional view sequentially illustrating Method 3 of manufacturing the vertical MOSFET according to Embodiment 6 of the present disclosure;

FIG. 23B is a cross-sectional view sequentially illustrating Method 3 of manufacturing the vertical MOSFET according to Embodiment 6 of the present disclosure;

FIG. 23C is a cross-sectional view sequentially illustrating Method 3 of manufacturing the vertical MOSFET according to Embodiment 6 of the present disclosure;

FIG. 23D is a cross-sectional view sequentially illustrating Method 3 of manufacturing the vertical MOSFET according to Embodiment 6 of the present disclosure;

FIG. 23E is a cross-sectional view sequentially illustrating Method 3 of manufacturing the vertical MOSFET according to Embodiment 6 of the present disclosure; and

FIG. 24 is a cross-sectional view illustrating a configuration example (Modified Example) of the vertical MOSFET 1 according to Embodiment 6 of the present disclosure.

### DETAILED DESCRIPTION

Some embodiments according to the present disclosure are descried below.

In the following explanations regarding the drawings, the same or similar components are denoted by the same or similar reference numerals. The drawings are illustrated schematically, and relationships between thicknesses and planar dimensions, and proportions of the thicknesses of the respective members are not drawn to scale. The specific thicknesses and dimensions therefore should be determined in accordance with the explanations below.

It should also be understood that the relationships or proportions of the dimensions between the drawings can differ from each other.

The following explanations may refer to the respective directions as an X-axis direction, a Y-axis direction, and a Z-axis direction. For example, the X-axis direction and the Y-axis direction are each a direction parallel to a top surface 10a of a GaN substrate 10 described below. Each of the X-axis direction and the Y-axis direction is referred to as a horizontal direction. The Z-axis direction is a direction orthogonal to the top surface 10a of the GaN substrate 10. The X-axis direction, the Y-axis direction, and the Z-axis are perpendicular to each other.

In the following explanations, the positive direction in the Z-axis may be referred to as an “upper side”, and the negative direction in the Z-axis may be referred to as a “lower side”. The definitions of the “upper side” and the “lower side” do not necessarily mean the directions vertical to the ground. In other words, the respective directions of the “upper side” and the “lower side” are not limited to the gravity direction. The definitions regarding the “upper side” and the “lower side” are used only for illustration purposes to define the relative positional relationship among regions, layers, films, and a substrate, which do not limit the technical idea of the present disclosure. For example, when the observing direction of the sheet is changed by 180 degrees, the definitions of the “upper side” and the “lower side” shall be reversed.

In the following explanations, the signs “+” and “−” added to the signs “p” and “n” used for semiconductor regions signify that the respective semiconductor regions have either a higher impurity concentration or a lower impurity concentration than other semiconductor regions without the sign “+” or “−” added. It should be understood that the respective semiconductor regions to which the same sign “p” (or the same sign “n”) is added do not necessarily or strictly have the same impurity concentration.

### Embodiment 1

### Configuration Example

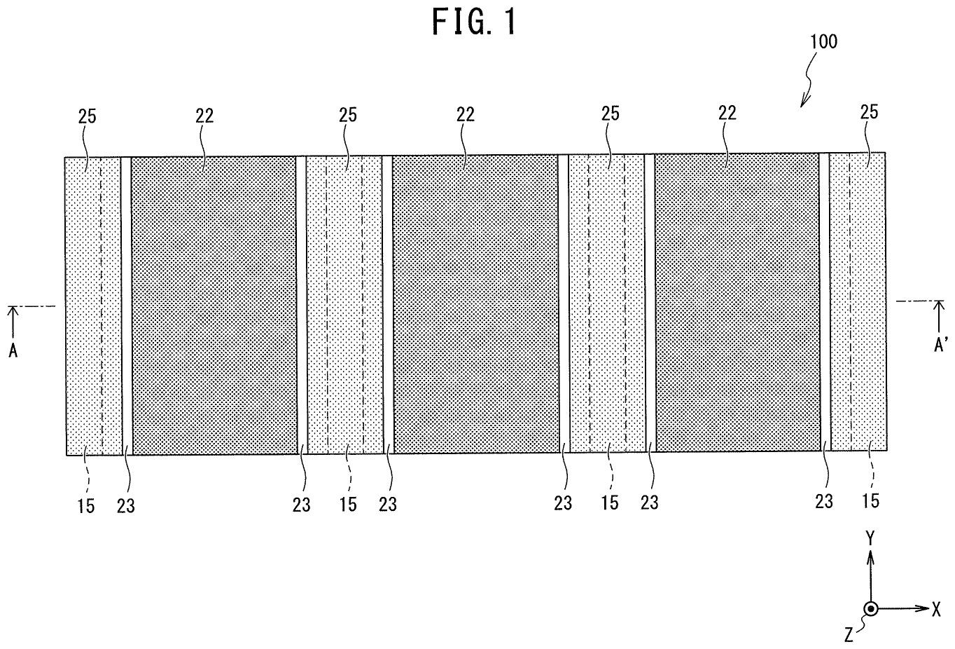

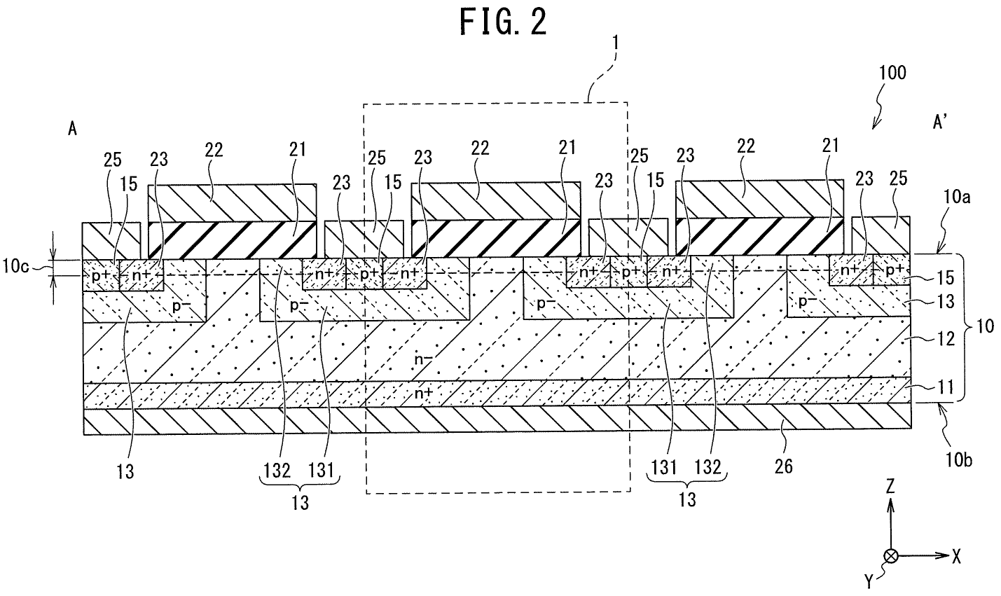

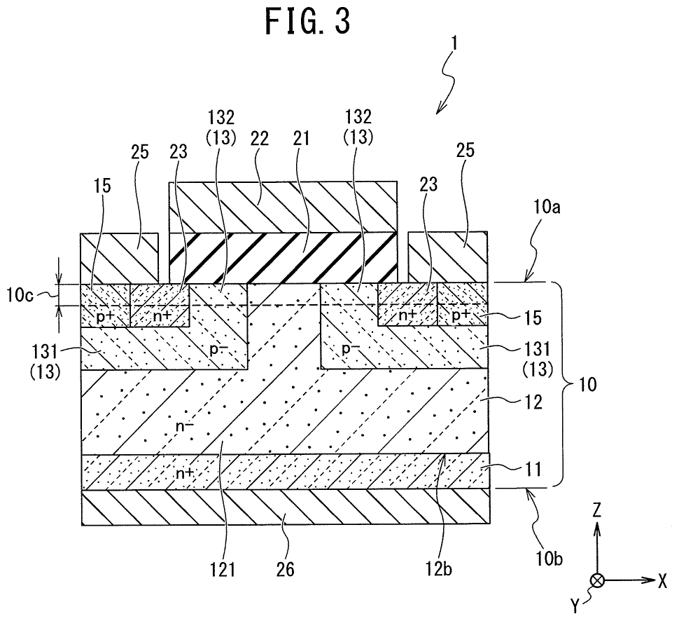

FIG. 1 is a plan view illustrating a configuration example of a gallium nitride (GaN) semiconductor device 100, which is an example of a “nitride semiconductor device” according to Embodiment 1 of the present disclosure. FIG. 2 is a cross-sectional view illustrating the configuration example of the GaN semiconductor device 100 according to Embodiment 1 of the present disclosure. FIG. 2 illustrates the cross section taken along line A-A′ in the plan view of FIG. 1. FIG. 3 is an enlarged cross-sectional view of FIG. 2, illustrating a configuration example of a single vertical MOSFET (a unit structure).

The GaN semiconductor device 100 illustrated in FIG. 1 and FIG. 2 is a power device. As illustrated in FIG. 1 and FIG. 2, the GaN semiconductor device 100 includes a GaN substrate 10 having a top surface 10a and a bottom surface 10b, and a plurality of vertical metal-oxide-semiconductor field-effect-transistors (MOSFETs) 1 provided in the GaN substrate 10. The plural vertical MOSFETs 1 are repeatedly arranged in one direction, such as in the X-axis direction, for example. Each of the vertical MOSFETs 1 is a unit structure, and the GaN semiconductor device 100 includes the plural unit structures aligned in one direction.

As illustrated in FIG. 1 to FIG. 3, the GaN substrate 10 includes a GaN single-crystal substrate 11 of n⁺-type, which is an example of a “nitride semiconductor substrate” according to the present disclosure, and a GaN layer 12 of n-type, which is an example of a “nitride semiconductor layer” according to the present disclosure, provided on the GaN single-crystal substrate 11. The GaN single-crystal substrate 11 is a chamfer-plane (c-plane) GaN single-crystal substrate of n⁺-type, for example. The GaN single-crystal substrate 11 includes n-type impurities, which are one or more kinds of elements of silicon (Si), oxygen (O), and germanium (Ge). For example, the GaN single-crystal substrate 11 includes Si as n-type impurities having an impurity concentration of Si that is 5×10¹⁷ cm⁻³ or higher.

The GaN single-crystal substrate 11 may be a low-dislocation free-standing substrate having a dislocation density of less than 1×10⁷ cm⁻². The use of the low-dislocation free-standing substrate as the GaN single-crystal substrate 11 leads the GaN layer 12 provided on the GaN single-crystal substrate 11 to also have a low dislocation density. The use of the low-dislocation free-standing substrate can also decrease a leak current in a power device regardless of whether to have a large area when formed in the GaN substrate 10. This enables a manufacturing apparatus to manufacture power devices at a high yield rate. Further, this can also avoid a deep diffusion of the implanted impurities along the dislocation during annealing.

The GaN layer 12 is a single-crystal GaN layer epitaxially grown on one of the surfaces of the GaN single-crystal substrate 11. The GaN layer 12 is formed by being doped with n-type impurities during the epitaxial growth step. The n-type impurities are Si, for example. The GaN layer 12 includes the n-type impurities of Si with a concentration in a range of 1×10¹⁵ cm⁻³ or higher and 5×101⁶ cm⁻³ or lower, for example.

The respective vertical MOSFETs 1 include a well region 13 of p-type provided toward the top surface 10a side of the GaN substrate 10 (toward the top surface of the GaN layer 12, which is an example of a “first surface” according to the present disclosure), and a contact region 15 of p+-type. The n-type region of the GaN layer 12 excluding the well region 13 and the contact region 15 is defined as a drift region 121. The drift region 121 is located between the top surface 10a of the GaN substrate 10 (the top surface of the GaN layer 12) and the bottom surface 12b of the GaN layer 12 (which is an example of a “second surface” according to the present disclosure). The drift region 121 is in contact with the n⁺-type GaN single-crystal substrate 11 provided on the bottom surface 12b side of the GaN layer 12. The respective vertical MOSFETs 1 further include a gate insulating film 21 provided on the top surface 10a side of the GaN substrate 10, a gate electrode 22 provided on the gate insulating film 21, a source electrode 25 provided on the top surface 10a side of the GaN substrate 10 so as to be in contact with a source region 23 of n⁺-type and the p⁺-type contact region 15, and a drain electrode 26 provided on the bottom surface 10b side of the GaN substrate 10 so as to be in contact with the n⁺-type GaN single-crystal substrate 11.

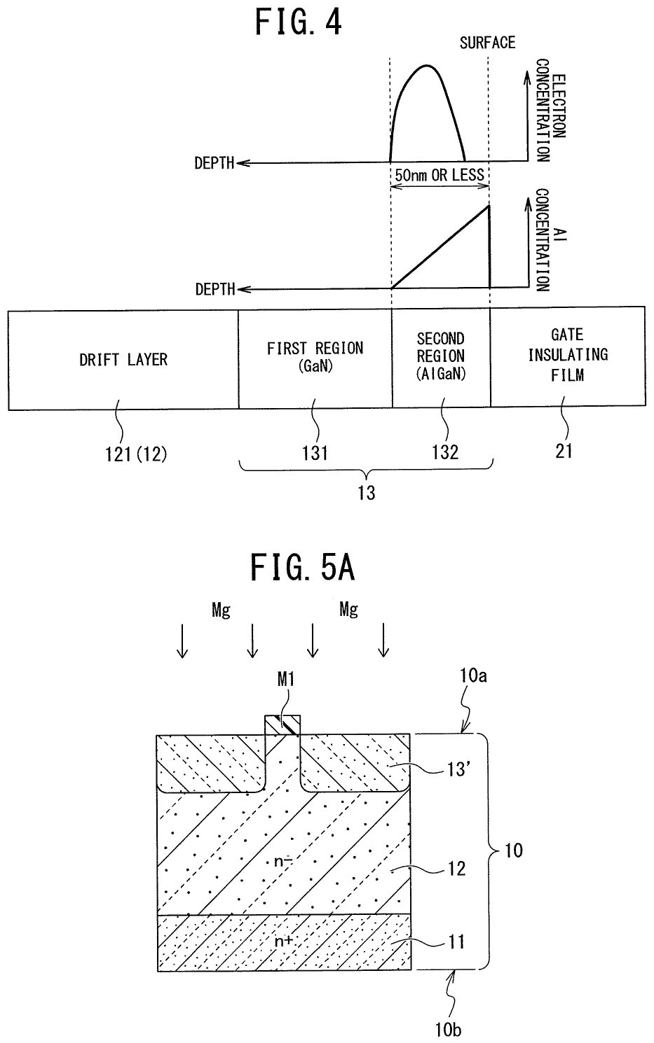

The well region 13 is a p-type layer formed such that p-type impurities such as Mg are ion implanted to a region toward the top surface 10a side of the GaN substrate 10 and are then subjected to annealing so as to be activated. The well region 13 includes the p-type impurities of Mg, for example, with a concentration in a range of 1× 10¹⁷ cm⁻³ or higher and 3×10¹⁸ cm⁻³ or lower. The well region 13 has a surface located at the same level as the top surface 10a of the GaN substrate 10 so as to be in contact with the gate insulating film 21. A first region 131 and a second region 132 are described in detail below with reference to FIG. 4.

The source region 23 is an n⁺-type layer formed such that n-type impurity ions such as Si or O are implanted to a region toward the top surface 10a side of the GaN substrate 10 and are then subjected to annealing so as to be activated. The source region 23 includes the n-type impurities of Si, for example, with a concentration in a range of 1×10¹⁹ cm⁻³ or higher and 5×10²⁰ cm⁻³ or lower. The source region 23 is arranged in the well region 13 under both sides of the gate electrode 22, and has a surface located at the same level as the top surface 10a of the GaN substrate 10. The source region 23 is located inside the well region 13 so as to be in contact with the well region 13.

The contact region 15 is a p⁺-type layer formed such that p-type impurity ions such as Mg are implanted to a region toward the top surface 10a side of the GaN substrate 10 and are then subjected to annealing so as to be activated. The contact region 15 includes the p-type impurities of Mg, for example, with a concentration in a range of 3×10¹⁸ cm⁻³ or higher and 1×10²¹ cm⁻³ or lower, and preferably in a range of 1×10¹⁹ cm⁻³ or higher and 2×10²⁰ cm⁻³ or lower.

The contact region 15 has a surface located at the same level as the top surface 10a of the GaN substrate 10. The contact region 15 is located inside the well region 13 so as to be in contact with the well region 13. The contact region 15 is also in contact with the source region 23.

The well region 13 is connected to the source electrode 25 via the contact region 15. The well region 13 thus has a potential fixed to a potential of the source electrode 25, which is a reference potential such as a ground potential (GND).

The gate insulating film 21 is a SiO₂ film, for example, having a thickness of 100 nanometers. The gate electrode 22 is located next to a region in which a channel is formed (referred to below as a “channel region”) via the gate insulating film 21. The gate electrode 22 includes metal such as Al, titanium (Ti), nickel (Ni), and tungsten (W) or polysilicon doped with impurities. The gate electrode 22 may include silicide such as WSi and NiSi instead.

The source electrode 25 is in ohmic contact with the source region 23 that is the n⁺-type layer and the contact region 15 that is the p⁺-type layer. The drain electrode 26 is in ohmic contact with the other surface of the n⁺-type GaN single-crystal substrate 11, which is on the opposite side of the surface in contact with the GaN layer 12.

The source electrode 25 and the drain electrode 26 each include Al, an Al—Si alloy, Ni, a Ni alloy, a Ti—Al alloy, or a Ni-gold (Au) alloy, for example. The source electrode 25 may include a barrier metal layer provided between the source electrode 25 and the source region 23. The drain electrode 26 may include a barrier metal layer between the drain electrode 26 and the n⁺-type GaN single-crystal substrate 11. The respective barrier metal layers may include titanium (Ti).

More particularly, the source electrode 25 and the drain electrode 26 may each be a stacked layer of a Ti layer and an Al layer or a stacked layer of a Ti layer and an Al—Si alloy layer. The source electrode 25 and the drain electrode 26 may include the same material or may include materials different from each other. The source electrode 25 may be an electrode also serving as a source pad (not illustrated) or may be an electrode provided independently of a source pad. The drain electrode 26 may be an electrode also serving as a drain pad (not illustrated) or may be an electrode provided independently of a drain pad.

FIG. 4 is a schematic view, as an example (Example) of the embodiment of the present disclosure, illustrating an Al concentration distribution in a depth direction from the top surface of the well region 13 and an electron concentration distribution in the depth direction upon a channel formation. As illustrated in FIG. 4, Al is not doped to the first region 131 of the well region 13. The concentration of Al in the first region 131 is zero or substantially zero. On the other hand, Al is doped to the second region 132 of the well region 13. The second region 132 has an Al concentration distribution in which the concentration of Al is highest on the surface in contact with the gate insulating film 21, and continuously decreases in the depth direction from the surface (toward the first region 131).

The second region 132 is a region of AlGaN having an inclination in which an Al composition ratio decreases in the depth direction. While FIG. 4 illustrates the case in which the inclination is indicated as a straight line, the inclination may be a curved line or a stepped line instead. The thickness of the second region 132, which is a depth from the top surface of the well region 13 to the first region 131, is 50 nanometers or less, and preferably 5 nanometers or less. The element Al included in the second region 132 is present mainly as a nitride.

The well region 31 is a p-type region doped with magnesium (Mg), for example. The Al composition is inclined and distributed in the p″-type region (the Mg-doped region) so that the region of AlGaN (the second region 132) having the thickness as thin as 50 nanometers or less is present. The first region 131 and the second region 133 each include Mg as p-type impurities. The electrons are widely distributed in a deep region inside the second region 132 during the channel formation, as illustrated in FIG. 4. Namely, a buried channel three-dimensionally distributed is formed in the second region 132.

The top surface 10a of the GaN substrate 10 is a polar surface, for example. The first region 131 and the second region 132 are stacked on the polar surface. The polar surface is a surface having no symmetry in the atom array in the axial direction taken along one surface of GaN crystals (in the direction perpendicular to one surface).

### <Manufacturing Methods>

Manufacturing methods 1 to 3, which are methods of manufacturing the vertical MOSFET 1 as illustrated with reference to FIG. 1 to FIG. 4, are described below. Manufacturing method 1 diffuses Al from the nitride film including Al toward the top surface 10a of the GaN substrate 10 and the adjacent region 10c so as to form the second region 132. Manufacturing method 2 implants of Al ions into the top surface 10a of the GaN substrate 10 and the adjacent region 10c so as to form the second region 132. Manufacturing method 3 forms the second region 132 by an epitaxial growth method. The respective methods are described in more detail below in the following sections I to III. The vertical MOSFET 1 is manufactured by use of various kinds of apparatuses, such as a deposition apparatus, an exposing apparatus, an ion-implanting apparatus, an annealing apparatus, and an etching apparatus. These apparatuses are collectively referred to below as a manufacturing apparatus.

### I. Manufacturing Method 1

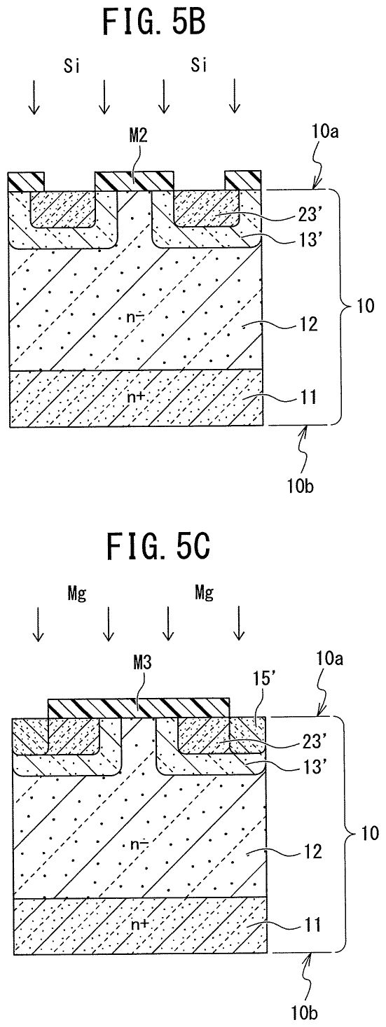

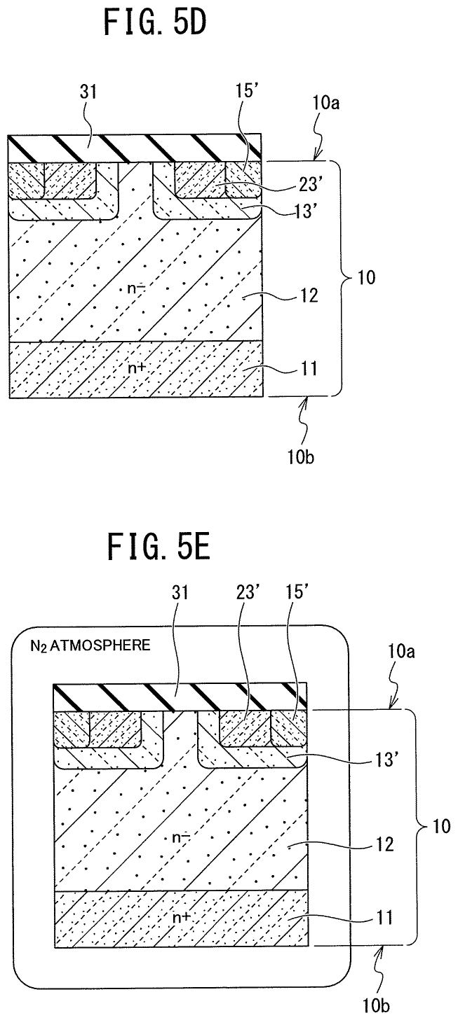

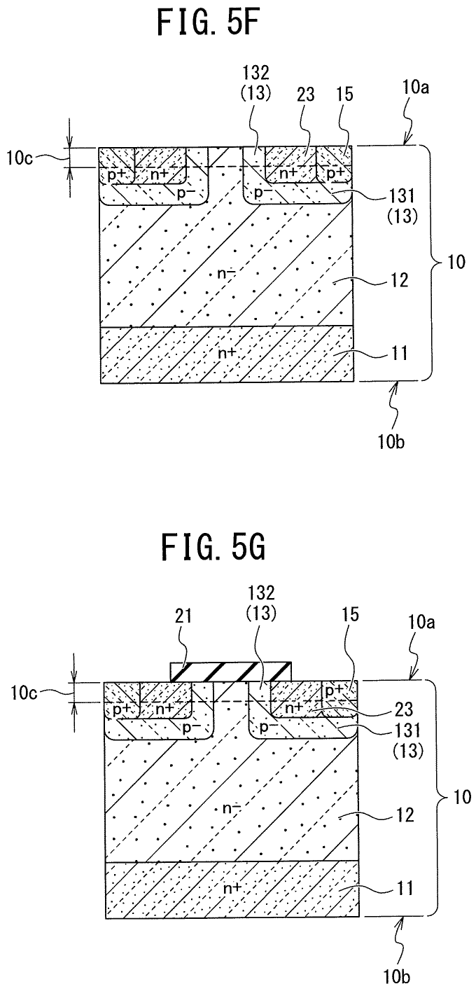

FIG. 5A to FIG. 5G are cross-sectional views sequentially illustrating Manufacturing method 1 for the vertical MOSFET 1 according to Embodiment 1 of the present disclosure. As illustrated in FIG. 5A, the manufacturing apparatus implants Mg ions as p-type impurities to an intended region (referred to below as a “well-formation region”) 13′ in the GaN substrate 10 in which the well region 13 is to be formed (refer to FIG. 3). For example, the manufacturing apparatus forms a mask M1 on the top surface 10a of the GaN substrate 10. The mask M1 is a SiO₂ film or a photoresist film that can be selectively removed from the GaN substrate 10. The mask M1 has a shape so as to open the upper side of the well-formation region 13′ while covering the upper side of the other regions. The manufacturing apparatus implants Mg ions to the GaN substrate 10 provided with the mask M1. The manufacturing apparatus then removes the mask M1 from the upper side of the GaN substrate 10 after the ion implantation.

The step of ion implantation of Mg illustrated in FIG. 5A sets an implantation energy (an accelerating voltage) and a dose of Mg so as to lead a concentration of Mg in the well-formation region 13′ to be 1×10¹⁷ cm⁻³. The step of ion implantation of Mg illustrated in FIG. 5A may be either single-step ion implantation in which the accelerating energy has a single condition or multiple-step ion implantation in which the accelerating energy has plural conditions.

Next, as illustrated in FIG. 5B, the manufacturing apparatus implants Si ions as n-type impurities to an intended region (referred to below as a “source-formation region”) 23′ in the GaN substrate 10 in which the source region is to be formed. For example, the manufacturing apparatus forms a mask M2 on the GaN substrate 10. The mask M2 is a SiO₂ film or a photoresist film. The mask M2 has a shape so as to open the upper side of the source-formation region 23′ while covering the upper side of the other regions. The manufacturing apparatus implants Si ions to the GaN substrate 10 provided with the mask M2. The manufacturing apparatus then removes the mask M2 from the upper side of the GaN substrate 10 after the ion implantation.

The step of ion implantation of Si illustrated in FIG. 5B sets an implantation energy (an accelerating voltage) and a dose of Si so as to lead a concentration of Si in the source-formation region 23′ to be 1×10¹⁹ cm⁻³.

Next, as illustrated in FIG. 5C, the manufacturing apparatus implants Mg ions as p-type impurities to an intended region (referred to below as a “contact-formation region”) 15′ in the GaN substrate 10 in which the contact region 15 is to be formed (refer to FIG. 3). For example, the manufacturing apparatus forms a mask M3 on the top surface 10a of the GaN substrate 10. The mask M3 is a SiO₂ film or a photoresist film that can be selectively removed from the GaN substrate 10. The mask M3 has a shape so as to open the upper side of the contact-formation region 15′ while covering the upper side of the other regions. The manufacturing apparatus implants Mg ions to the GaN substrate 10 provided with the mask M3. The manufacturing apparatus then removes the mask M3 from the upper side of the GaN substrate 10 after the ion implantation.

The step of ion implantation of Mg illustrated in FIG. 5C sets an implantation energy (an accelerating voltage) and a dose of Mg so as to lead a concentration of Mg in the contact-formation region 15′ to be 1×10¹⁹ cm⁻³

Next, as illustrated in FIG. 5D, the manufacturing apparatus deposits a nitride film including Al, such as an aluminum nitride (AlN) film 31, on the top surface 10a of the GaN substrate 10. A thickness of the AlN film 31 is in a range of 100 nanometers or greater and 500 nanometers or less, for example. A method of depositing the AlN film 31 may be determined as appropriate, and examples include a metal organic chemical vapor deposition (MOCVD) method, a sputtering method, an atomic layer deposition (ALD) method, and a plasma enhanced chemical vapor deposition (PECVD) method.

Next, as illustrated in FIG. 5E, the manufacturing apparatus subjects the AlN film 31 and the GaN substrate 10 covered with the AlN film 31 to annealing. The annealing is rapid thermal annealing, for example. The annealing is executed under the conditions of a maximum temperature in a range of 1000° C. or higher and 1500° C. or lower, a annealing time at the maximum temperature in a range of 1 minute or longer and 60 minutes or shorter, and an atmosphere of N₂, for example. The execution of the annealing activates Mg and Si introduced to the GaN substrate 10, so as to form the well region 13, the n⁺-type source region 23, and the p⁺-type contact region 15 and further define the drift region 121, as illustrated in FIG. 5F.

This annealing can also recover defects to some extent in the GaN substrate 10 caused by the ion implantation. In addition, the AlN film 31 has a function of preventing nitrogen atoms from being released from the GaN substrate 10 during the annealing. The GaN substrate 10, if the nitrogen atoms are released, is provided with nitrogen voids at the released positions. The nitrogen voids if formed could serve as donor-type defects and thus inhibit the expression of the p-type characteristics. The GaN substrate 10, which is subjected to the annealing while being covered with the AlN film 31, can avoid the release of the nitrogen atoms and prevent the expression of the p-type characteristics from being inhibited.

The execution of the annealing also diffuses Al included in the AlN film 31 from the AlN film 31 toward the top surface 10a of the GaN substrate 10 and the adjacent region 10c, which is within 50 nanometers from the top surface 10a in a depth direction, and preferably within 5 nanometers from the top surface 10a in the depth direction, for example. This diffusion provides the well region 13 with the first region 131 not including Al and the second region 132 including Al. The second region 132 is a region of AlGaN, which is GaN with Al doped.

The Al concentration distribution in the second region 132 (AlGaN) is as shown in FIG. 4, for example. The Al concentration is highest on the top surface of the second region 132, namely, on the top surface 10a of the GaN substrate 10, and decreases in a continuous or stepwise state from the top surface 10a toward the first region 131. The Al concentration on the top surface of the second region 132 is in a range of 10 at % or higher and 30 at % or lower, for example.

The annealing also leads Al to be diffused from the AlN film 31 toward the regions other than the well region 13, such as the source region 23 and the contact region 15. The execution of the annealing thus dopes Al to the surface of the source region 23 and the adjacent region and further to the surface of the contact region 15 and the adjacent region. The manufacturing apparatus then removes the AlN film 31 from the upper side of the GaN substrate 10 after the annealing.

Next, as illustrated in FIG. 5G, the manufacturing apparatus forms the gate insulating film 21 on the top surface 10a of the GaN substrate 10. For example, a SiO₂ film is deposited as the gate insulating film 21 so as to have a thickness of 100 nanometers, for example.

Next, the manufacturing apparatus forms the gate electrode 22 (refer to FIG. 3) and the source electrode 25 (refer to FIG. 3). For example, the manufacturing apparatus deposits a Ti film and an Al film sequentially on the top surface 10a of the GaN substrate 10 provided with the gate insulating film 21, and delineates these films so as to form the gate electrode 22 and the source electrode 25. The manufacturing apparatus also forms the drain electrode 26 (refer to FIG. 3) on the bottom surface 10b side of the GaN substrate 10. For example, the manufacturing apparatus deposits a Ti film and an Al film sequentially on the bottom surface 10b side of the GaN substrate 10, and delineates these films so as to form the drain electrode 26. The vertical MOSFET 1 as illustrated in FIG. 3 is thus completed through the process described above.

### II. Manufacturing Method 2

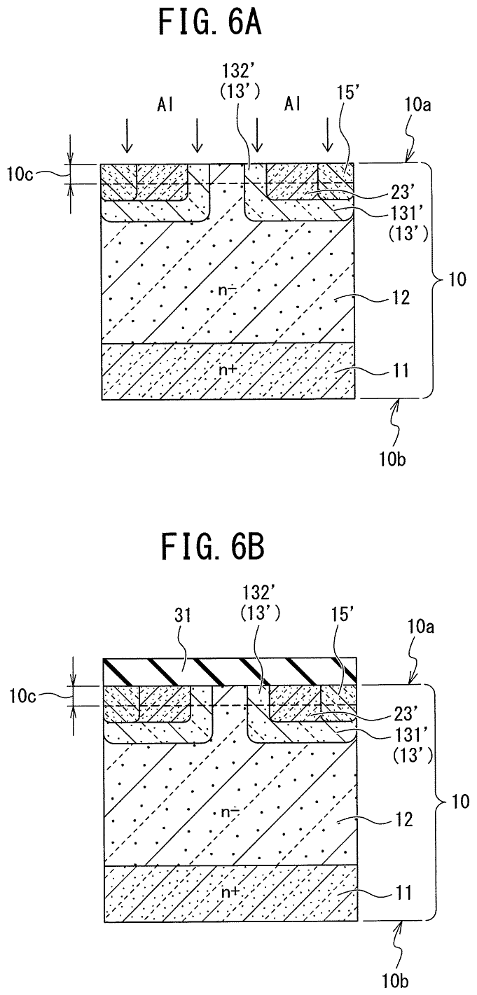

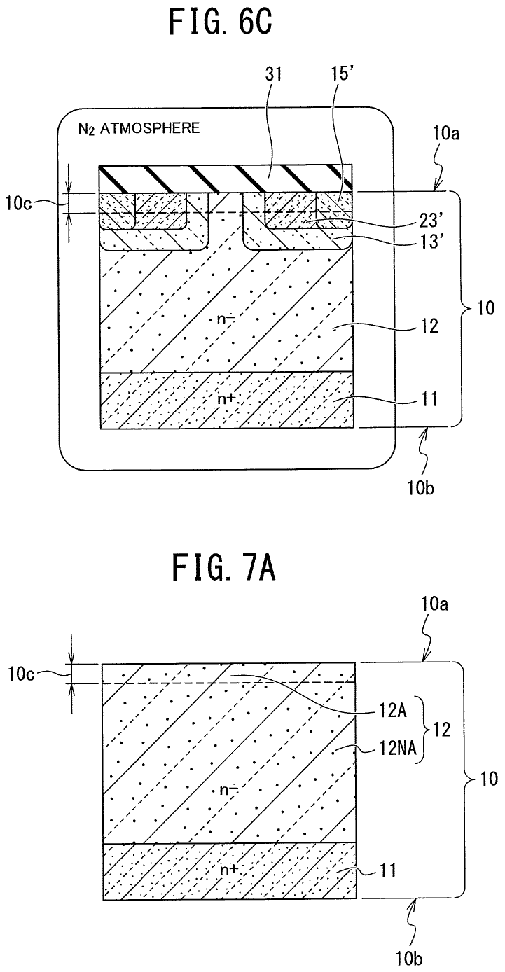

FIG. 6A to FIG. 6C are cross-sectional views sequentially illustrating Manufacturing method 2 for the vertical MOSFET 1 according to Embodiment 1 of the present disclosure. Manufacturing method 2 illustrated in FIG. 6A has the same manufacturing steps, as those in Manufacturing method 1 as described with reference to FIG. 5C, until the Mg ions are implanted to the contact-formation region 15′. As illustrated in FIG. 5C, the manufacturing apparatus implants Mg ions to the GaN substrate 10 by use of the mask M3, and then removes the mask M3 from the upper side of the GaN substrate 10.

Next, as illustrated in FIG. 6A, the manufacturing apparatus implants Al ions to the top surface 10a of the GaN substrate 10 and the adjacent region 10c. A dose of Al ions to be implanted is in a range of 1×10²¹ cm⁻² or greater and 1×10²² cm⁻² or less, for example. The well-formation region 13′ is thus provided with a first region 131′ without Al doped and a second region 132′ with Al doped. The second region 132′ is a region of AlGaN, which is GaN with Al doped.

The ion implantation of Al is executed so as to adjust the implantation energy such that the Al concentration is highest on the surface of the second region 132′, namely, on the top surface 10a of the GaN substrate 10, and decreases in a continuous or stepwise state from the top surface 10a toward the first region 131′. The ion implantation of Al is also executed so as to adjust the implantation energy such that the Al concentration on the top surface of the second region 132′ is in a range of 10 at % or higher and 30 at % or lower, for example.

This step also leads Al ions to be implanted to the regions other than the well-formation region 13′, such as the source-formation region 23′ and the contact-formation region 15′. Al ions are thus doped to the surface of the source-formation region 23′ and the adjacent region and further to the surface of the contact-formation region 15′ and the adjacent region. The step illustrated in FIG. 6A may execute the implantation of Al ions to the well-formation region 13′ in a state in which the source-formation region 23′ and the contact-formation region 15′ are covered with a mask (not illustrated). This can prevent Al ions from being implanted to the source-formation region 23′ and the contact-formation region 15′.

Next, as illustrated in FIG. 6B, the manufacturing apparatus deposits a nitride film including Al, such as the aluminum nitride (AlN) film 31, on the top surface 10a of the GaN substrate 10. A thickness of the AlN film 31 is in a range of 100 nanometers or greater and 500 nanometers or less, for example. A method of depositing the AlN film 31 may be determined as appropriate, and examples include a MOCVD method, a sputtering method, an ALD method, and a PECVD method. Alternatively, the manufacturing apparatus may deposit a passivation film other than the AlN film in the step illustrated in FIG. 6B, since Al ions have been introduced to the top surface 10a of the GaN substrate 10 and the adjacent region 10c. Manufacturing method 2 may deposit, as the passivation film, a SiO₂ film or a SiN film, or a stacked film including at least one or more of the AlN film, SiO₂ film, and the SiN film, for example.

Next, as illustrated in FIG. 6C, the manufacturing apparatus subjects the GaN substrate 10 covered with the AlN film 31 (or the passivation film) to annealing. The conditions for the annealing are the same as those in Manufacturing method 1. The execution of the annealing activates Mg and Si introduced to the GaN substrate 10, so as to form the p⁻-type well region 13, the n⁺-type source region 23, and the p⁺-type contact region 15, and further define the drift region 121, as illustrated in FIG. 5F.

The following steps are the same as those in Manufacturing method 1. The manufacturing apparatus removes the AlN film 31 from the upper side of the GaN substrate 10 after the annealing. Next, the manufacturing apparatus forms the gate insulating film 21 (refer to FIG. 5G) on the top surface 10a of the GaN substrate 10. Next, the manufacturing apparatus forms the gate electrode 22 (refer to FIG. 3) and the source electrode (refer to FIG. 3). The manufacturing apparatus further forms the drain electrode 26 (refer to FIG. 3) on the bottom surface 10b side of the GaN substrate 10. The vertical MOSFET 1 as illustrated in FIG. 3 is thus completed through the steps as described above.

### III. Manufacturing Method 3

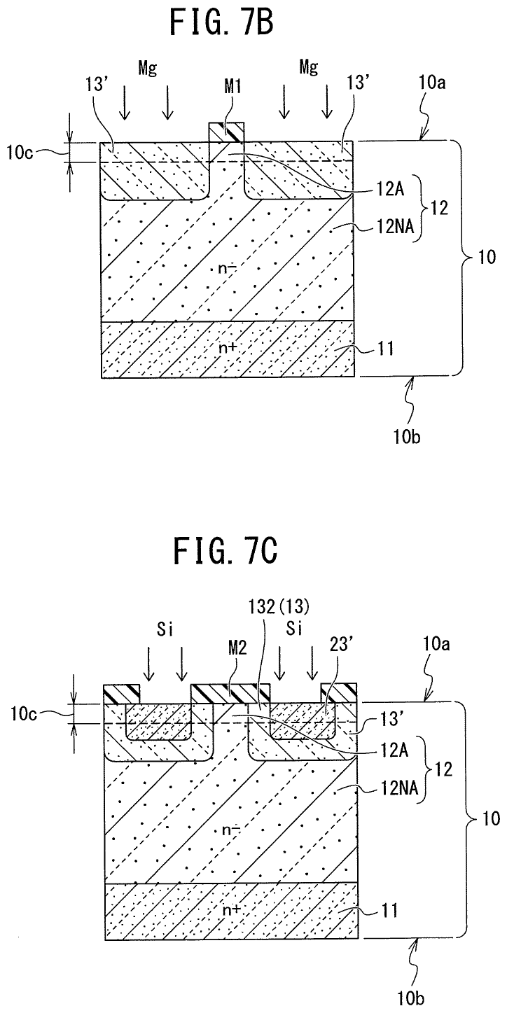

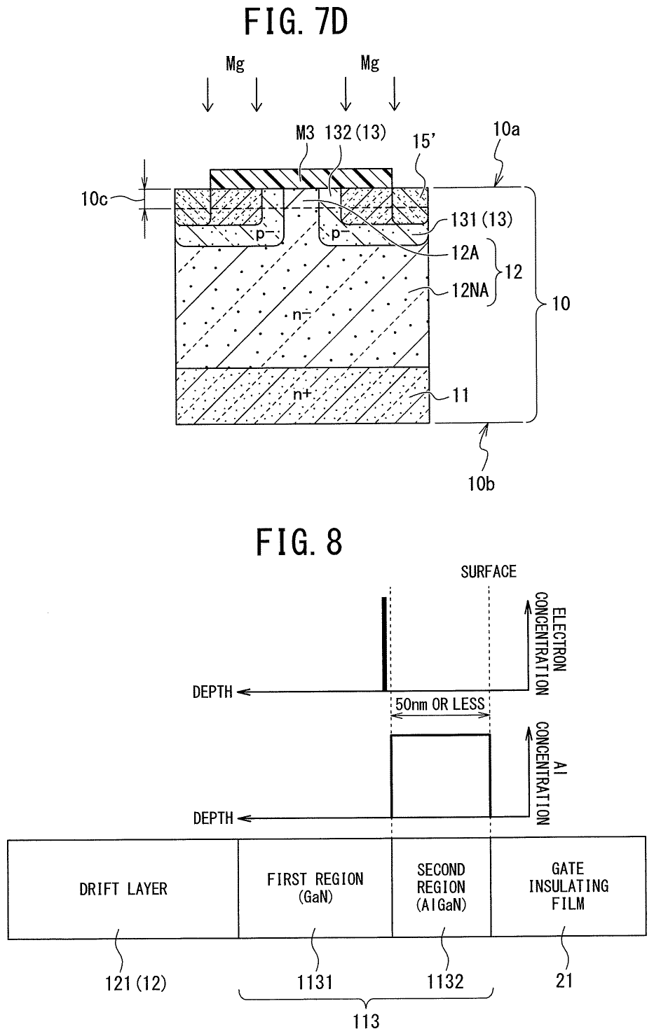

FIG. 7A to FIG. 7D are cross-sectional views sequentially illustrating Manufacturing method 3 for the vertical MOSFET 1 according to Embodiment 1 of the present disclosure. In FIG. 7A, the manufacturing apparatus epitaxially grows the n-type GaN layer 12 on the n⁺-type GaN single-crystal substrate 11 so as to form the GaN substrate 10. The epitaxial growth step dopes Al to the top surface of the GaN layer 12 and the adjacent region, that is, to the top surface 10a of the GaN substrate 10 and the adjacent region 10c, but does not dope Al to the other regions. Namely, the manufacturing apparatus first forms a GaN layer 12NA not including Al, and then forms an AlGaN layer 12A by the epitaxial growth method.

The epitaxial growth step also sets the Al composition to be inclined such that the Al concentration is highest on the top surface of the AlGaN region, and decreases in a continuous or stepwise state from the top surface in the depth direction, as illustrated in FIG. 4, for example. A thickness of AlGaN formed by the epitaxial growth method is set to 50 nanometers or smaller, and preferably 5 nanometers or smaller, for example. The Al concentration on the top surface of AlGaN is in a range of 10 at % or higher and 30 at % or lower, for example.

Next, as illustrated in FIG. 7B, the manufacturing apparatus forms, on the GaN substrate 10, a mask M1 having a shape that opens the upper side of the well-formation region 13′ while covering the upper side of the other regions. The manufacturing apparatus implants Mg ions as p-type impurities to the well-formation region 13′ in the GaN substrate 10 by use of the mask M1. The manufacturing apparatus then removes the mask M1 from the upper side of the GaN substrate 10 after the ion implantation.

Next, as illustrated in FIG. 7C, the manufacturing apparatus forms, on the GaN substrate 10, a mask M2 having a shape that opens the upper side of the source-formation region 23′ while covering the upper side of the other regions. The manufacturing apparatus implants Si ions as n-type impurities to the source-formation region 23′ in the GaN substrate 10 by use of the mask M2. The manufacturing apparatus then removes the mask M2 from the upper side of the GaN substrate 10 after the ion implantation.

Next, as illustrated in FIG. 7D, the manufacturing apparatus forms, on the GaN substrate 10, a mask M3 having a shape that opens the upper side of the contact-formation region 15′ while covering the upper side of the other regions. The manufacturing apparatus implants Mg ions as p-type impurities to the contact-formation region 15′ in the GaN substrate 10 by use of the mask M3. The manufacturing apparatus then removes the mask M3 from the upper side of the GaN substrate 10 after the ion implantation.

The following steps are the same as those after the step illustrated in FIG. 6B in Manufacturing method 2. The manufacturing apparatus deposits the nitride film including Al, such as the AlN film 31, on the top surface 10a of the GaN substrate 10. Alternatively, the manufacturing apparatus may deposits a passivation film instead of the AlN film 31, as in the case of Manufacturing method 2, since Al ions have been introduced to the top surface 10a of the GaN substrate 10 and the adjacent region 10c.

Next, the manufacturing apparatus subjects the GaN substrate 10 covered with the AlN film 31 (or the passivation film) to annealing. The conditions for the annealing are the same as those in Manufacturing method 1. The execution of the annealing activates Mg and Si introduced to the GaN substrate 10, so as to form the n⁺-type source region 23 and the p⁺-type contact region 15, and further define the drift region 121, as illustrated in FIG. 5F.

The manufacturing apparatus removes the AlN film 31 (or the passivation film) from the upper side of the GaN substrate 10 after the annealing. Next, the manufacturing apparatus forms the gate insulating film 21 (refer to FIG. 5G) on the top surface 10a of the GaN substrate 10. Next, the manufacturing apparatus forms the gate electrode 22 (refer to FIG. 3) and the source electrode 25 (refer to FIG. 3). The manufacturing apparatus further forms the drain electrode 26 (refer to FIG. 3) on the bottom surface 10b side of the GaN substrate 10. The vertical MOSFET 1 as illustrated in FIG. 3 is thus completed through the process described above.

### Comparison between Comparative Examples 1 and 2

FIG. 8 is a schematic view, as Comparative Example 1 of the present disclosure, illustrating an Al concentration distribution in a depth direction from a top surface of a well region 113 and an electron concentration distribution in the depth direction upon a channel formation. As illustrated in FIG. 8, Al is not doped to the first region 1131 of the well region 113 in Comparative Example 1. The concentration of Al in the first region 1131 is zero or substantially zero. On the other hand, Al is doped to the second region 1132 of the well region 113. The concentration of Al is constant in the second region 1132 in Comparative Example 1 from the surface in contact with the gate insulating film 21 in the depth direction (toward the first region 1131). The second region 1132 is a region of AlGaN in which an Al composition ratio is constant in the depth direction. The well region 113 is a p-type region doped with Mg. During the channel formation, electrons are distributed within a narrow area at an interface between the first region 1131 and the second region 1132 and the adjacent region, as illustrated in FIG. 8. Namely, two-dimensional electron gas (2DEG) is formed at the interface.

Comparative Example 2 of the present disclosure is a vertical MOSFET not including the second region (AlGaN) in the well region but provided with a channel on the first region (GaN). Comparative Example 2 has a structure in which the second region 1132 (AlGaN) is removed from the region between the first region 1131 and the gate insulating film 21 (SiO₂) illustrated in FIG. 8. The structure of Comparative Example 2 is provided with a channel at a GaN/SiO₂ interface.

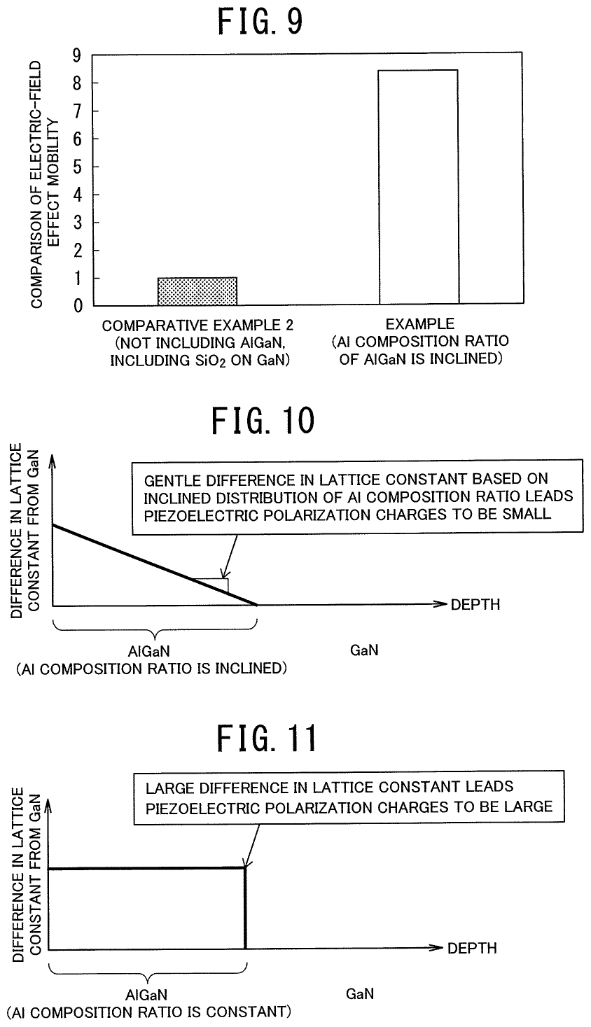

FIG. 9 is a graph showing results of experiments executed by the inventors, in which electric field mobility is compared between Example and Comparative Example 2. In the data shown in FIG. 9, Example is illustrated with the vertical MOSFET, as illustrated in FIG. 4, including the p-type well region 13 provided with the first region 131 without Al doped, and the second region 132 with Al doped that has the composition ratio inclined in the depth direction. As shown in FIG. 9, the results revealed that Example has higher electric-field effect mobility than Comparative Example 2 without provided with the second region (AlGaN). The electric-field effect mobility in Example is eight or greater on the basis of the electric-field effect mobility of Comparative Example 2 that is presumed to be one.

Example of the present disclosure can form a three-dimensional channel inside the crystals in the second region 132 (AlGaN) of the well region 13, which is different from a channel formed at a GaN/SiO₂ interface that would cause scattering or trapping because of interface defects (in the case not provided with composition-inclined AlGaN), so as to lead the channel mobility to approximate to bulk mobility to avoid trapping of minority carriers (electrons, for example).

Further, Example of the present disclosure provides the second region 132 (AlGaN) having the inclination composition, so as to decrease polarization charges caused in AlGaN and facilitate a control of a threshold voltage. This point is described in more detail below with reference to FIG. 10 and FIG. 11. FIG. 10 is a graph schematically showing a relation of a difference in lattice constant between AlGaN and GaN in the well region 13 in Example of the present disclosure. FIG. 11 is a graph schematically showing a relation of a difference in lattice constant between AlGaN and GaN in the well region 113 in Comparative Example 1 of the present disclosure. As shown in the comparison between FIG. 10 and FIG. 11, Example indicates the inclination regarding the Al composition ratio in AlGaN, which leads the difference in the lattice constant between AlGaN and GaN to be gentle. The gentle difference in the lattice constant leads piezoelectric polarization charges to be small. In contrast, Comparative Example 1 indicates the constant Al composition ratio regarding the AlGaN, which leads the difference in the lattice constant between AlGaN and GaN to be large. The large difference in the lattice constant leads the piezoelectric polarization charges to be large. Example of the present disclosure thus can facilitate the control of the threshold voltage.

### EFFECTS OF EMBODIMENT 1

As described above, the GaN semiconductor device 100 according to Embodiment 1 of the present disclosure includes the n-type GaN substrate 10, the p-type well region 13 provided in the GaN substrate 10, and the gate insulating film 21 provided on the top surface 10a side of the GaN substrate 10 so as to cover the well region 13. The well region 13 includes the first region 131 without Al doped, and the second region 132 with Al doped, the second region 132 being provided on the first region 131. The second region 132 has the Al concentration distribution in which the Al concentration is highest on the top surface 10a in contact with the gate insulating film 21 and decreases in a continuous or stepwise state from the top surface 10a toward the first region 131.

The configuration described above, in which the Al compound layer formed inside the crystals of the GaN substrate 10 is provided with a three-dimensional channel, can decrease a scattering influence or trapping present at the interface with the gate insulating film 21, so as to lead the channel mobility to approximate to the bulk mobility. This can improve the channel mobility to decrease the channel resistance. Since the channel resistance accounts for a large part of the ON-resistance in the vertical MOSFET 1 provided in the GaN substrate 10, the decrease of the channel resistance can decrease the ON-resistance. This embodiment thus can achieve the vertical MOSFET 1 with the low ON-resistance while having the high channel mobility. The effects of the present embodiment are described in more detail below including the problems with the vertical MOSFET.

Decreasing the ON-resistance of the MOSFET can reduce a power loss during operation. The ON-resistance of the MOSFET is a sum of resistances present between a drain and a source. Since a thickness of a drift layer (producing drift resistance) varies depending on a target value of breakdown voltage of the vertical MOSFET, dominant resistance factors of the vertical MOSFET vary.

In the vertical MOSFET provided in the GaN substrate, the channel resistance serves as a large component accounting for several tens of percents of the ON-resistance when the target value of the breakdown voltage is a class of 1 kV. The improvement in the channel mobility can be a way of decreasing the channel resistance. The channel mobility indicates a degree of facilitating the transmission of minority carriers in an inverted layer (namely, in the channel) formed on the top surface of the GaN substrate. For example, when the minority carriers scatter because of charged defects in the gate insulating film or roughness on the surface of the GaN substrate, the channel mobility decreases, while the channel resistance increases.

Embodiment 1 forms the region in which Al is present while having a distribution with a diffusion figure in the GaN crystals by thermal diffusion. The Al compound layer having the inclined composition is formed while having the distribution defined by the thermal diffusion of Al in the GaN substrate so that the Al composition ratio is inclined from the top surface of the GaN substrate in the depth direction to gradually decrease. The thickness of the Al compound layer is determined in accordance with a diffusion constant of Al in the GaN substrate, and the variation is thus presumed to be small. Further, as compared with Comparative Example 1 shown in FIG. 11 (having the constant Al concentration), Embodiment 1 has the configuration in which the Al compound layer having the inclined Al composition ratio has a lattice constant closer to GaN, and is thus presumed to have a smaller amount of the polarization charges and ensure high mass-production stability (mass-production applicability).

Further, the present embodiment, which provides the Al compound layer having the composition inclination inside the GaN crystals by the thermal diffusion, leads the channel mobility to be about 50% of the bulk mobility, so as to achieve a tremendous improvement in mobility. This is presumed to be because the Al compound layer formed inside the GaN crystals provides the three-dimensional channel to serve as a buried channel, so as to decrease the scattering influence present at the interface with the gate insulating film. The present embodiment thus can achieve the vertical MOSFET having the low ON-resistance with the high channel mobility.

### Modified Example

Manufacturing methods 1 to 3 according to Embodiment 1 are illustrated above with the case in which the impurities included in the well-formation region 13′, the source-formation region 23′, and the contact-formation region 15′ are activated by the annealing as illustrated in FIG. 5E so as to simultaneously form the p-type well region 13, the n⁺-type source region 23, and the p⁺-type contact region 15. Alternatively, the present embodiment may form the well region 13, the source region 23, and the contact region 15 independently of each other through annealing at different timings, instead of the simultaneous formation. For example, the present embodiment may implant Mg ions to the well-formation region 13′ and then form a passivation film to execute first annealing, so as to form the p-type well region 13. The present embodiment then may implant Si ions to the source-formation region 23′ and implant Mg ions to the contact-formation region 15′ to form a passivation film and subject second annealing, so as to form the n⁺-type source region 23 and the p⁺-type contact region 15. The execution of the first annealing and the second annealing independently of each other can increase the alternatives for the characteristics of each of the well region 13 and the source region 23, so as to facilitate the independent control of the respective regions. This modified example may be applied not only to Embodiment 1 but also to other embodiments described below.

### Embodiment 2

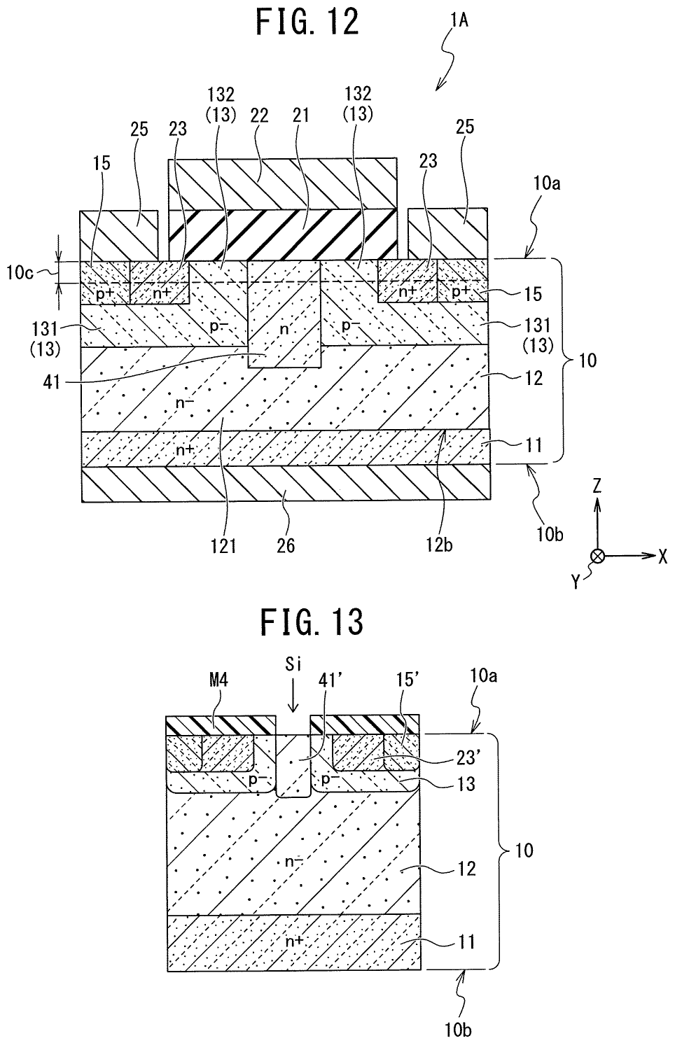

FIG. 12 is a cross-sectional view illustrating a configuration example of a vertical MOSFET 1A (a unit structure) according to Embodiment 2 of the present disclosure. As illustrated in FIG. 12, the vertical MOSFET 1A includes a JFET region 41 of n-type, which is an example of a “high-concentration region” according to the present disclosure, provided in the GaN layer 12 and having a higher concentration of n-type impurities than the n-type drift layer. The JFET region 41 is located between one of the well regions 13 and another well region 13 next to each other in the horizontal direction, which is the X-axis direction, for example.

The JFET region 41 also includes Al doped to the surface and the adjacent region, as in the case of the well region 13. The Al concentration distribution in the JFET region 41 has a configuration in which the Al concentration is highest on the top surface, and decreases in a continuous or stepwise state from the top surface in the depth direction, for example, toward the drift region 121. The provision of the JFET region can achieve a reduction in ON-resistance of the vertical MOSFET 1A. The other configurations are the same as those in the vertical MOSFET 1 described in Embodiment 1.

FIG. 13 is a cross-sectional view illustrating a method of manufacturing the vertical MOSFET 1A according to Embodiment 2 of the present disclosure. The manufacturing method illustrated in FIG. 13 includes the same manufacturing steps as those in Manufacturing method 1 according to Embodiment 1 as described with reference to FIG. 5C until Mg ions are implanted to the contact-formation region 15′. As illustrated in FIG. 5C, the manufacturing apparatus implants Mg ions to the GaN substrate 10 by use of the mask M3, and then removes the mask M3 from the upper side of the GaN substrate 10.

Next, as illustrated in FIG. 13, the manufacturing apparatus implants Si ions as n-type impurities to an intended region (referred to below as a “JFET-formation region”) 41′ in which the JFET region 41 is to be formed (refer to FIG. 12). For example, the manufacturing apparatus forms a mask M4 on the top surface 10a of the GaN substrate 10. The mask M4 is a SiO₂ film or a photoresist film that can be selectively removed from the GaN substrate 10. The mask M4 has a shape so as to open the upper side of the JFET-formation region 41′ while covering the upper side of the other regions. The manufacturing apparatus implants Si ions to the GaN substrate 10 provided with the mask M4. The manufacturing apparatus then removes the mask M4 from the upper side of the GaN substrate 10 after the ion implantation. The following steps are the same as those after FIG. 5D in Manufacturing method 1 according to Embodiment 1. The vertical MOSFET 1A as illustrated in FIG. 12 is thus completed through the process described above.

The vertical MOSFET 1A according to Embodiment 2 also includes the second region 132 that has the Al concentration distribution in which the Al concentration is highest on the top surface 10a in contact with the gate insulating film 21 and decreases in a continuous or stepwise state from the top surface 10a toward the first region 131, as in the case of the vertical MOSFET 1 according to the Embodiment 1. This configuration can provide the three-dimensional channel in the second region 132, so as to achieve the low ON-resistance while having high channel mobility. The vertical MOSFET 1A including the JFET region 41 can further reduce the ON-resistance.

### Embodiment 3

Embodiments 1 and 2 described above are illustrated with the case in which the respective vertical MOSFETs 1 and 1A are a planar-type MOSFET. Embodiments according to the present disclosure are not limited to the planar-type vertical MOSFET, and may be applied to a trench-gate vertical MOSFET.

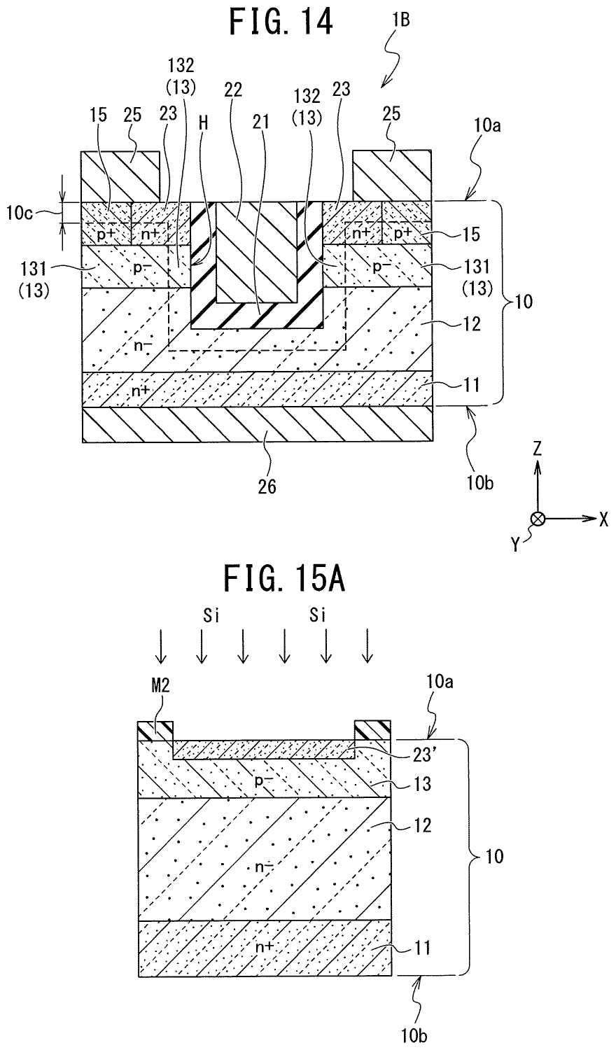

FIG. 14 is a cross-sectional view illustrating a configuration example of a vertical MOSFET 1B (a unit structure) according to Embodiment 3 of the present disclosure. As illustrated in FIG. 14, the vertical MOSFET 1B according to Embodiment 3 has a trench H provided in the GaN substrate 10. The trench H is open toward the top surface 10a of the GaN substrate 10. The trench H is formed to have a greater depth than the p″-type well region 13 so that the bottom of the trench H reaches the n″-type GaN layer 12 (the drift region 121).

The gate insulating film 21 and the gate electrode 22 are arranged inside the trench H. The respective side and bottom surfaces inside the trench H are covered with the gate insulating film 21. The gate electrode 22 is buried in the trench H with the gate insulating film 21 interposed. The trench-gate vertical MOSFET 1B includes the well region 13 serving as a channel region that is opposed to the gate electrode 22 via the gate insulating film 21 provided on the side surface of the trench H.

The well region 13 in the vertical MOSFET 1B according to Embodiment 3 also includes the first region 131 without Al doped, and the second region 132 with Al doped, the second region 132 being provided on the first region 131. The second region 132 faces the side surface of the trench H so as to be in contact with the gate insulating film 21 along the side surface. The second region 132 and the first region 131 are sequentially arranged in this order from the side surface of the trench H in the horizontal direction (the X-axis direction, for example). The second region 132 has the Al concentration distribution in which the Al concentration is highest on the surface, which is an example of the “first surface” according to the present disclosure, in contact with the gate insulating film 21 and decreases in a continuous or stepwise state from the surface toward the first region 131.

The side surface of the trench H provided in the GaN substrate 10 is a nonpolar surface, for example. The first region 131 and the second region 132 are stacked on the nonpolar surface. The term “nonpolar surface” refers to a surface having symmetry in the configuration of atoms in an axial direction of a cross section taken along one surface of CaN crystals (in a direction perpendicular to the surface).

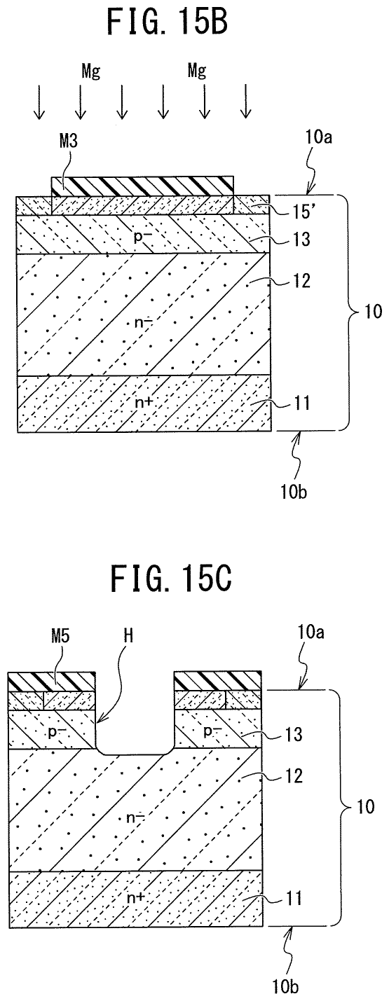

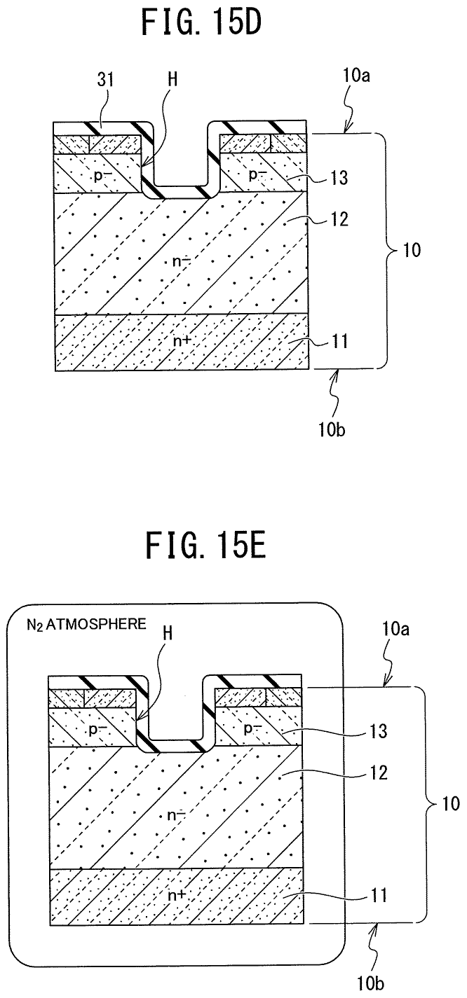

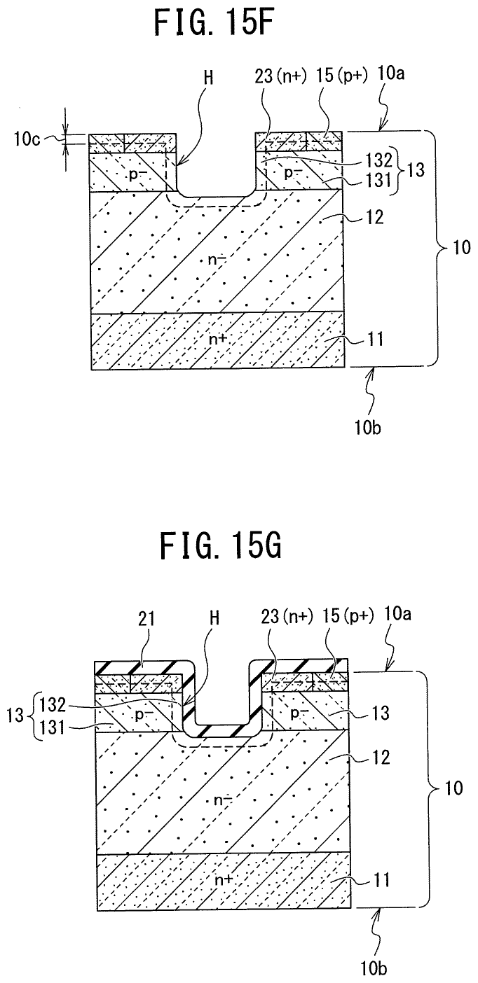

A manufacturing method according to this embodiment is described below. FIG. 15A to FIG. 15G are cross-sectional views illustrating the method of manufacturing the vertical MOSFET 1B according to Embodiment 3 of the present disclosure. In FIG. 15A, the manufacturing apparatus epitaxially grows the n-type GaN layer 12 including Si as n-type impurities and the p-type GaN layer (the p-type well region 13) including Mg as p-type impurities sequentially on the GaN single-crystal substrate 11.

Next, the manufacturing apparatus forms, on the GaN substrate 10, a mask M2 having a shape that opens the upper side of the source-formation region 23′ while covering the upper side of the other regions. The manufacturing apparatus implants Si ions as n-type impurities to the source-formation region 23′ in the GaN substrate 10 by use of the mask M2. The manufacturing apparatus then removes the mask M2 from the upper side of the GaN substrate 10 after the ion implantation.

Next, as illustrated in FIG. 15B, the manufacturing apparatus forms, on the GaN substrate 10, a mask M3 having a shape that opens the upper side of the contact-formation region 15′ while covering the upper side of the other regions. The manufacturing apparatus implants Mg ions as p-type impurities to the contact-formation region 15′ in the GaN substrate 10 by use of the mask M3. The manufacturing apparatus then removes the mask M3 from the upper side of the GaN substrate 10 after the ion implantation.

Next, as illustrated in FIG. 15C, the manufacturing apparatus forms, on the GaN substrate 10, a mask M5 having a shape that opens the upper side of the intended region in which the trench H is to be formed while covering the upper side of the other regions. The manufacturing apparatus subjects the GaN substrate 10 to dry etching by use of the mask M5 so as to form the trench H. The manufacturing apparatus then removes the mask M5 from the upper side of the GaN substrate 10 after the formation of the trench H.

Next, as illustrated in FIG. 15D, the manufacturing apparatus deposits a nitride film including Al, such as the aluminum nitride (AlN) film 31, on the top surface 10a of the GaN substrate 10. Embodiment 3 deposits the AlN film 31 not only on the top surface 10a of the GaN substrate 10 but also on the respective side and bottom surfaces of the trench H. The thickness of the AlN film 31 is in a range of 100 nanometers or greater and 500 nanometers or less, for example. The method of depositing the AlN film 31 may be determined as appropriate, and examples include a MOCVD method, a sputtering method, an ALD method, and a PECVD method.

Next, as illustrated in FIG. 15E, the manufacturing apparatus subjects the AlN film 31 and the GaN substrate 10 covered with the AlN film 31 to annealing. The conditions for the annealing are the same as those in Manufacturing method 1 according to Embodiment 1. The execution of the annealing activates Mg and Si introduced to the GaN substrate 10, so as to form the n⁺-type source region 23 and the p⁺-type contact region 15, as illustrated in FIG. 5F.

The execution of the annealing also diffuses Al included in the AlN film 31 toward the top surface 10a of the GaN substrate 10 and the adjacent region 10c. In Embodiment 3, Al is further diffused from the AlN film 31 covering the side surface of the trench H in the horizontal direction. The diffusion of Al from the AlN film 31 toward the GaN substrate 10 is within 50 nanometers from the top surface 10a of the GaN substrate 10 in the depth direction (or from the side surface of the trench H in the horizontal direction), and preferably within 5 nanometers from the top surface 10a in the depth direction (or from the side surface of the trench H in the horizontal direction). This diffusion provides the well region 13 with the first region 131 without Al doped and the second region 132 with Al doped, as illustrated in FIG. 15F. The second region 132 is a region of AlGaN, which is GaN with Al doped. The second region 132 (AlGaN) is formed on the side surface of the trench H and the adjacent region. The manufacturing apparatus then removes the AlN film 31 from the upper side of the GaN substrate 10 after the annealing.

Next, as illustrated in FIG. 15G, the manufacturing apparatus forms the gate insulating film 21 on the top surface 10a side of the GaN substrate 10. For example, a SiO₂ film is deposited as the gate insulating film 21 so as to have a thickness of 100 nanometers, for example. The gate insulating film 21 is formed not only on the top surface 10a of the GaN substrate 10 but also on the respective side and bottom surfaces of the trench H.

Next, the manufacturing apparatus forms the gate electrode 22 (refer to FIG. 14) and the source electrode 25 (refer to FIG. 14) on the top surface 10a side of the GaN substrate 10 provided with the gate insulating film 21. The gate electrode 22 is buried in the trench H with the gate insulating film 21 interposed. The manufacturing apparatus also forms the drain electrode 26 (refer to FIG. 14) on the bottom surface 10b side of the GaN substrate 10. The vertical MOSFET 1B as illustrated in FIG. 14 is thus completed through the process described above.

The vertical MOSFET 1B according to Embodiment 3 also includes the second region 132 that has the Al concentration distribution in which the Al concentration is highest on the surface in contact with the gate insulating film 21 (on the side surface of the trench H, for example) and decreases in a continuous or stepwise state from the top surface 10a toward the first region 131, as in the case of the vertical MOSFET 1 according to the Embodiment 1. This configuration can provide the three-dimensional channel in the second region 132, so as to achieve the vertical MOSFET 1B with low ON-resistance while having high channel mobility. Further, the configuration of the vertical MOSFET 1B, which is the trench-gate type, can decrease a cell pitch more than a planer-type vertical MOSFET, so as to reduce the ON-resistance more effectively.

### Embodiment 4

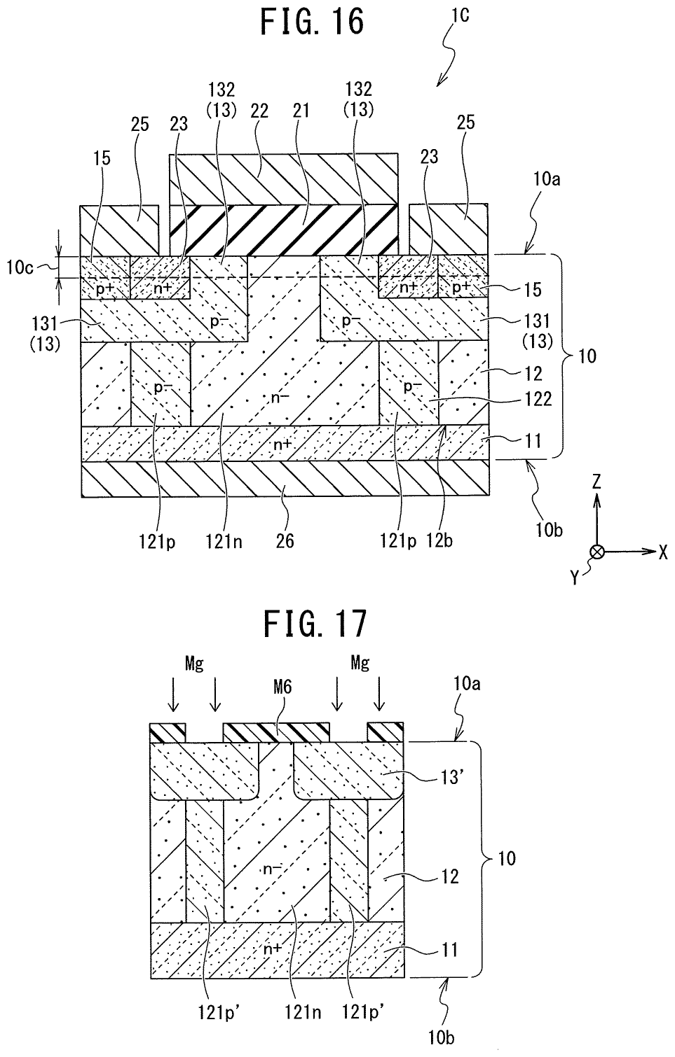

FIG. 16 is a cross-sectional view illustrating a configuration example of a vertical MOSFET 1C (a unit structure) according to Embodiment 4 of the present disclosure. As illustrated in FIG. 16, the drift region 121 included in the vertical MOSFET 1C according to Embodiment 4 has a super junction structure (a SJ structure). The drift region 121 includes n-type pillars 121n and p-type pillars 121p (also referred to as “pillars of a second conductivity-type” according to the present disclosure). The n-type pillars 121n and the p-type pillars 121p are arranged next to each other in the horizontal direction, which is the X-axis direction, for example. The p-type pillars 121p extend from the bottom of the well region 13 toward the bottom surface 12b of the GaN layer 12 so as to be in contact with the well region 13 and the GaN single-crystal substrate 11. One n-type pillar 121n is interposed between one of the pillars 121p and another pillar 121p located adjacent to each other.

The pillars 121p have the same or substantially the same p-type impurity concentration as the well region 13. The pillars 121n have a lower n-type impurity concentration than the source region 23. The respective pillars 121n serve as a current path between the GaN single-crystal substrate 11 and the well region 13. The other configurations are the same as those in the vertical MOSFET 1 described in Embodiment 1.

FIG. 17 is a cross-sectional view illustrating a method of manufacturing the vertical MOSFET 1C according to Embodiment 4 of the present disclosure. The manufacturing method illustrated in FIG. 17 includes the same manufacturing steps as those in Manufacturing method 1 according to Embodiment 1 as described with reference to FIG. 5A until Mg ions are implanted to the well-formation region 13′. As illustrated in FIG. 5A, the manufacturing apparatus implants Mg ions to the GaN substrate 10 by use of the mask M1, and then removes the mask M1 from the upper side of the GaN substrate 10.

Next, as illustrated in FIG. 17, the manufacturing apparatus implants Mg ions as p-type impurities to intended regions (referred to below as “pillar-formation regions”) 121p′ in which the pillars 121p are to be formed (refer to FIG. 17). For example, the manufacturing apparatus forms a mask M6 on the top surface 10a of the GaN substrate 10. The mask M6 is a SiO₂ film or a photoresist film that can be selectively removed from the GaN substrate 10. The mask M6 has a shape so as to open the upper side of the pillar-formation regions 121p′ while covering the upper side of the other regions. The manufacturing apparatus implants Mg ions deeply into the GaN substrate 10 provided with the mask M6. The manufacturing apparatus then removes the mask M6 from the upper side of the GaN substrate 10 after the ion implantation. For example, the region of the n-type GaN layer 12 excluding the well-formation region 13′ and the pillar-formation regions 121p′ serves as the respective n-type pillars 121n. The following steps are the same as those after FIG. 5B described in Manufacturing method 1 according to Embodiment 1. The execution of the annealing as illustrated in FIG. 5E activates Mg and Si introduced to the GaN substrate 10, so as to form the well region 13, the pillars 121p, the n⁺-type source region 23, and the p⁺-type contact region 15 and further define the pillars 121n. The vertical MOSFET 1C as illustrated in FIG. 16 is thus completed through the process described above.

The vertical MOSFET 1C according to Embodiment 4 also includes the second region 132 that has the Al concentration distribution in which the Al concentration is highest on the top surface 10a in contact with the gate insulating film 21 and decreases in a continuous or stepwise state from the top surface 10a toward the first region 131, as in the case of the vertical MOSFET 1 according to the Embodiment 1. This configuration can provide the three-dimensional channel in the second region 132, so as to achieve the vertical MOSFET 1C with low ON-resistance while having high channel mobility.

Further, the vertical MOSFET 1C, which includes the drift region 121 having the SJ structure, can increase the impurity concentration in the n-type pillars 121 to reduce the drift resistance while avoiding a decrease in breakdown voltage. This configuration can further reduce the ON-resistance in the vertical MOSFET 1C. The reduction in the ON-resistance can further contribute to the channel resistance in the ON-resistance. This can enhance the effect of reducing the channel resistance due to the presence of the second region 132 (the composition-inclined Al layer).

### Modified Example

Embodiment 4 is illustrated above with the case in which Mg ions are implanted deeply into the GaN substrate 10 provided with the mask M6 so as to form the p-type pillars 121p. The method of forming the p-type pillars 121p in Embodiment 4 is not limited to this case. The p-type pillars 121p may be formed by a multiple-step epitaxial-growth method. For example, the p-type pillars 121p may be formed by a method including a step of forming the GaN layer by an epitaxial-growth method and a step of implanting Mg ions to the GaN layer thus obtained by use of the mask M6, and repeating these steps several times, followed by the annealing as described with reference to FIG. 5E, so as to manufacture the vertical MOSFET 1C as illustrated in FIG. 16.

### Embodiment 5

Embodiments 1 to 4 described above are illustrated with the case in which the gate insulating film 21 is the SiO₂ film, but the present disclosure is not limited to this case. Embodiments 1 to 4 may include the gate insulating film 21 that can be a film other than the SiO₂ film, such as an aluminum oxide film (an Al₂O₃ film), or can be a film having a stacked structure including at least either the SiO₂ film or the Al₂O₃ film.

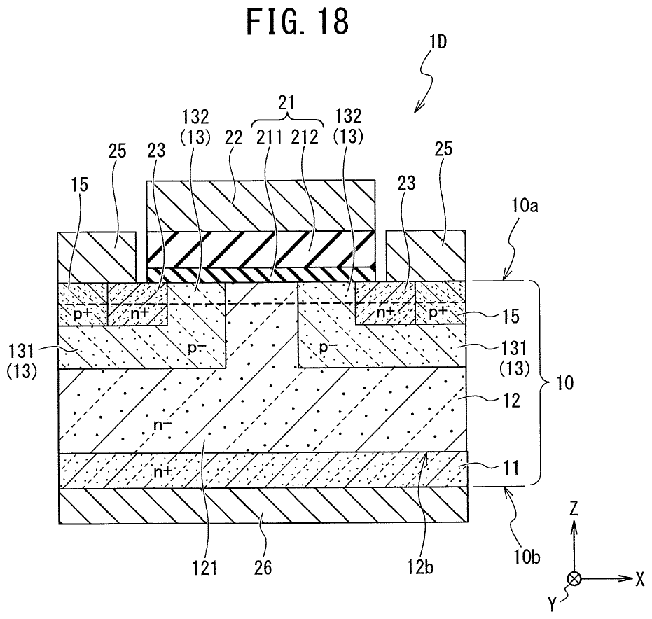

FIG. 18 is a cross-sectional view illustrating a configuration example of a vertical MOSFET 1D (a unit structure) according to Embodiment 5 of the present disclosure. As illustrated in FIG. 18, the gate insulating film 21 includes an oxynitride silicon film (a SiON film) 211, which is an example of a “Si oxynitride film” according to the present disclosure, and a silicon oxide film (a SiO₂ film) 212, which is an example of a “Si oxide” according to the present disclosure, provided on the SiON film 211. The SiON film 211 and the SiO₂ film 212 are stacked in this order on the GaN layer 12,

The SiON film 211 has a smaller thickness than the SiO₂ film 212. The thickness of the SiON film 211 is in a range of 0.5 nanometers or greater and 5 nanometers or smaller, and the thickness of the SiO₂ film 212 is in a range of 30 nanometers or greater and 200 nanometers or smaller, for example.

As a modified example, the gate insulating film 21 may include an aluminum oxide film (an Al₂O₃ film), which is an example of an “Al oxide” according to the present disclosure, instead of the SiO₂ film 212. Alternatively, the gate insulating film 21 may have a structure including the SiON film, the SiO₂ film, and the Al₂O₃ film sequentially stacked on the top surface 10a of the GaN substrate 10 in this order. The other configurations are the same as those in the vertical MOSFET 1 described in Embodiment 1.

The configuration of the vertical MOSFET 1D according to Embodiment 5 can also provide the three-dimensional channel in the second region 132, so as to achieve low ON-resistance while having high channel mobility. Further, the vertical MOSFET 1D, which includes the SiON film under the SiO₂ film 212 (or the Al₂O₃ film), can suppress surface oxidation of the GaN layer 12 upon the formation of the SiO₂ film 212 (or the Al₂O₃ film), so as to avoid a cause of positive fixed charges. This thus can increase the threshold voltage.

### Embodiment 6

Another embodiment according to the present disclosure may have a configuration in which not only the Al concentration but also the Mg concentration can have a difference between the first region 131 and the second region 132 of the well region 13.

### I. Configuration Example 1

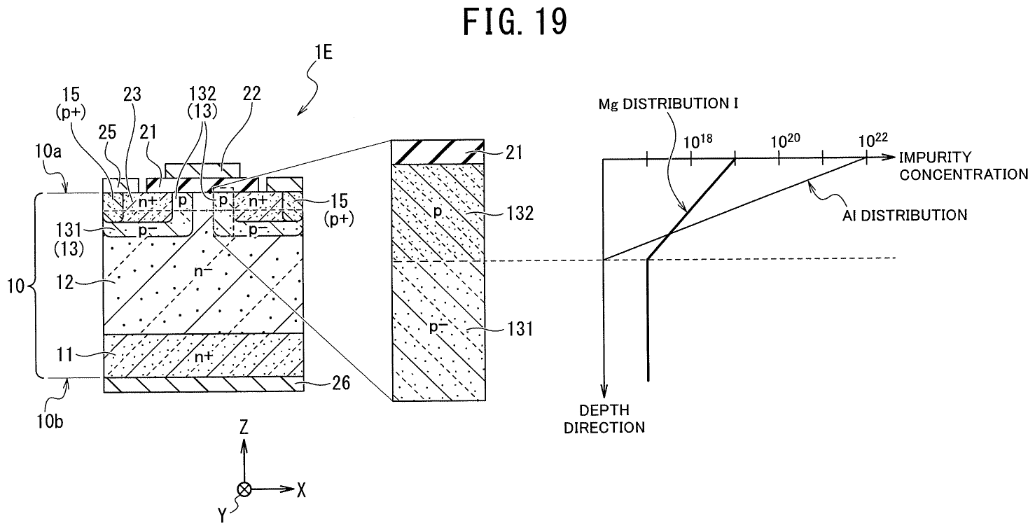

FIG. 19 is a view schematically illustrating a vertical MOSFET 1E (Configuration Example 1) according to Embodiment 6 of the present disclosure. In particular, the view on the right side in FIG. 19 is a cross-sectional view illustrating a configuration example of the vertical MOSFET 1E (a unit structure), the view on the left side in FIG. 19 is a graph showing an Al concentration distribution (also referred to below as an “Al distribution”) and a Mg concentration distribution (also referred to below as a “Mg distribution”) I in the first region 131 and the second region 132, and the view in the middle in FIG. 19 is an enlarged cross-sectional view of the first region 131 and the second region 132. The axis of ordinates of the graph on the left side in FIG. 19 indicates a depth from the top surface 10a of the GaN substrate 10 (the surface on which the second region 132 and the gate insulating film 21 are in contact with each other, for example), and the axis of abscissas indicates an impurity concentration. The character “10^{x}” (x is an integer) indicated on the axis of abscissas in FIG. 19 refers to 1×10 cm⁻³.

The well region 13 in the vertical MOSFET 1E illustrated in FIG. 19 also includes the first region 131 without Al doped (namely, the Al concentration is zero or substantially zero), and the second region 132 with Al doped, the second region 132 being provided on the first region 131, as in the case of the vertical MOSFETs described above in the respective embodiments. The second region 132 has the Al concentration distribution in which the Al concentration is highest on the top surface 10a in contact with the gate insulating film 21 and decreases in a continuous or stepwise state from the top surface 10a toward the first region 131. FIG. 19 illustrates the mode as an example in which the Al concentration continuously decreases from the top surface 10a toward the first region 131.

The second region 132 included in the vertical MOSFET 1E has a higher concentration of Mg than the first region 131. The second region 132 is p-type, and the first region 131 is p-type. The maximum value (the peak value) of the Mg concentration in the second region 132 is greater than the maximum value of the Mg concentration in the first region 131. For example, the Mg concentration in the second region 132 is highest on the top surface 10a in contact with the gate insulating film 21 and the adjacent region. The Mg concentration on the top surface 10a in contact with the gate insulating film 21 and the adjacent region is also referred to below as a “surface Mg concentration”. The surface Mg concentration in the second region 132 is in a range of 5×10¹⁸ cm⁻³ or higher and 5×10¹⁹ cm⁻³ or lower, and can be about 1×10¹⁹ cm⁻³, for example. The boundary between the first region 131 and the second region 132 is located in a range of 0.5 nanometers or deeper and 3 nanometers or shallower in the depth direction from the top surface 10a, for example.

As illustrated in FIG. 19, the second region 132 has the Mg concentration distribution in which the Mg concentration continuously increases from the first region 131 toward the top surface 10a in contact with the gate insulating film 21. In particular, the second region 132 has a composition-inclined profile in which the Mg concentration gradually increases from the first region 131 toward the top surface 10a in contact with the gate insulating film 21. For example, the Mg concentration at the boundary between the first region 131 and the second region 132 is in a range of 5×10¹⁶ cm⁻³ or higher and 5×10¹⁷ cm⁻³ or lower, and can be 1×10¹⁷ cm 3, for example. The second region 132 has the Mg concentration distribution in which the Mg concentration continuously increases from the boundary with the first region 131 toward the top surface 10a.

The Mg concentration in the first region 131 is highest at the boundary between the first region 131 and the second region 132. The Mg concentration in the first region 131 is constant in the depth direction, and can be 1×10¹⁷ cm⁻³, for example. The first region 131 does not have a composition inclination.

The vertical MOSFET 1E (Configuration Example 1) according to Embodiment 6 also includes the second region 132 that has the Al concentration distribution in which the Al concentration is highest on the top surface 10a in contact with the gate insulating film 21 and decreases in a continuous or stepwise state from the top surface 10a toward the first region 131, as in the case of the vertical MOSFET 1 according to the Embodiment 1. This configuration can provide the three-dimensional channel in the second region 132, so as to achieve the vertical MOSFET with low ON-resistance while having high channel mobility.

The use of the composition-inclined AlGaN in the second region 132 provides the channel in the second region 132 separately from the top surface 10a of the second region 132. This can prevent the threshold voltage from excessively increasing or the channel mobility from excessively decreasing regardless of whether the surface Mg concentration in the second region 132 increases in order to deal with hole trapping. This configuration example thus can achieve both low hole trapping and high mobility.

### II. Configuration Example 2

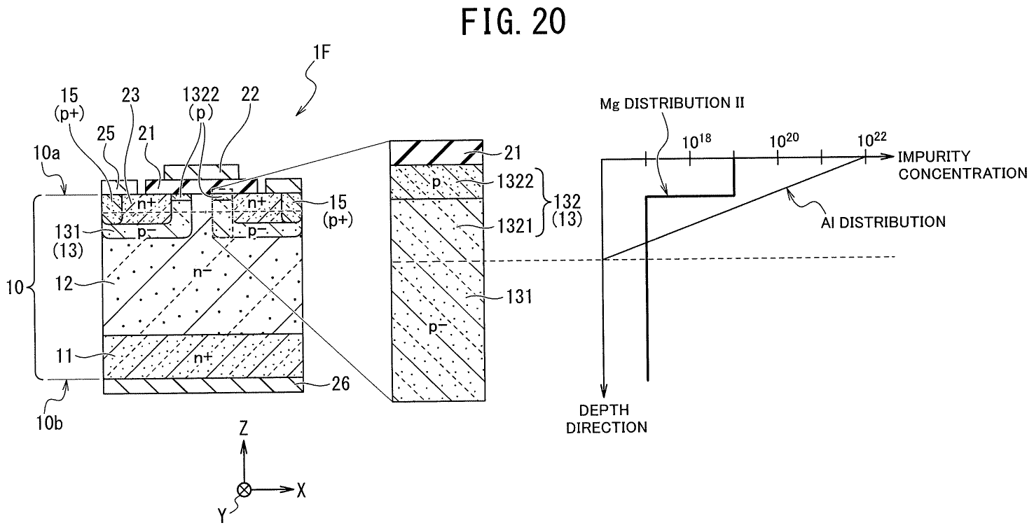

Configuration example 1 is illustrated above with the case in which the Mg concentration in the second region 132 continuously increases from the first region 131 side toward the top surface 10a in contact with the gate insulating film 21. The Mg concentration is not limited to the continuous increase, but may be a stepwise increase. FIG. 20 is a view schematically illustrating a vertical MOSFET IF (Configuration Example 2) according to Embodiment 6 of the present disclosure. As in the case illustrated in FIG. 19, the view on the right side in FIG. 20 is a cross-sectional view illustrating a configuration example of a unit structure, the view on the left side in FIG. 20 is a graph showing an Al distribution and a Mg distribution II, and the view in the middle in FIG. 20 is an enlarged cross-sectional view of the first region 131 and the second region 132. The definition regarding the axis of ordinates and the axis of abscissas of the graph in FIG. 20 is the same as that in FIG. 19.

Configuration Example 2 illustrated in FIG. 20 differs from Configuration Example 1 in the Mg concentration distribution in the second region 132. The second region 132 in the MOSFET 1F has the Mg concentration distribution in which the Mg concentration increases in a stepwise state from the first region 131 side toward the top surface 10a in contact with the gate insulating film 21. For example, the second region 132 has the Mg concentration distribution in which the Mg concentration is high only around the top surface 10a and the adjacent region, and is the same as that in the first region 131 under these regions. The second region 132 can be defined by an upper region 1322 toward the top surface 10a and the adjacent region and by a lower region 1321 under the upper region, in which the upper region 1322 is p-type, and the lower region 1321 is p-type.

For example, the Mg concentration in the upper region 1322 is in a range of 5×10¹⁶ cm⁻³ or higher and 5×10¹⁷ cm⁻³ or lower, and can be 1×10¹⁷ cm 3. The Mg concentration in each of the lower region 1321 and the p-type first region 131 is constant in the depth direction, for example, and is 1×10¹⁷ cm 3. The other configurations are the same as those in Configuration Example 1.

The vertical MOSFET IF (Configuration Example 2) has the Al concentration distribution similar to that in the vertical MOSFET 1E (Configuration Example 1), so as to provide the three-dimensional channel in the second region 132. This configuration can achieve the vertical MOSFET with low ON-resistance while having high channel mobility. Further, Configuration Example 2 also provides the channel in the second region 132 separately from the top surface 10a, as in the case of Configuration Example 1. This can prevent the threshold voltage from excessively increasing or the channel mobility from excessively decreasing regardless of whether the surface Mg concentration in the second region 132 increases in order to deal with hole trapping. This configuration example thus can achieve both low hole trapping and high mobility.

### III. Configuration Example 3

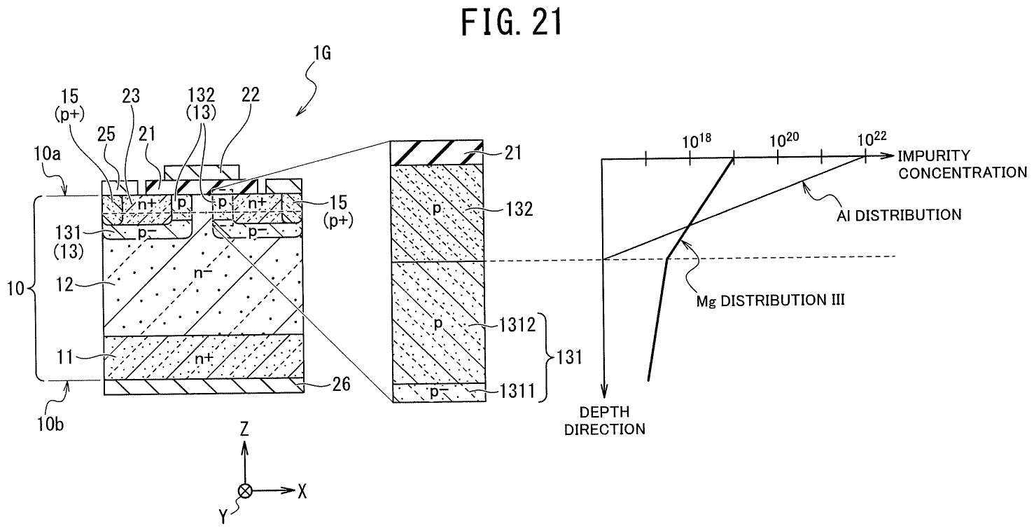

Configuration example 1 is illustrated above with the case in which the Mg concentration in the first region 131 is constant in the depth direction. The first region 131 does not necessarily have the constant Mg concentration in the depth direction, but may have a Mg concentration that decreases in the depth direction instead. Namely, the Mg concentration in the first region 131 may increase as closer to the second region 132. FIG. 21 is a view schematically illustrating a vertical MOSFET 1G (Configuration Example 3) according to Embodiment 6 of the present disclosure. As in the case illustrated in FIG. 19, the view on the right side in FIG. 21 is a cross-sectional view illustrating a configuration example of a unit structure, the view on the left side in FIG. 21 is a graph showing an Al distribution and a Mg distribution III, and the view in the middle in FIG. 21 is an enlarged cross-sectional view of the first region 131 and the second region 132. The definition regarding the axis of ordinates and the axis of abscissas of the graph in FIG. 21 is the same as that in FIG. 19.

Configuration Example 3 illustrated in FIG. 21 differs from Configuration Example 1 in the Mg concentration distribution in the first region 131. The first region 131 in the MOSFET 1G has the Mg concentration distribution in which the Mg concentration increases in a continuous or stepwise state from the n-type GaN layer 12 side toward the boundary with the second region 132. In particular, the first region 131 has a composition-inclined profile in which the Mg concentration gradually increases from the n-type GaN layer 12 side toward the boundary with the second region 132. The first region 131 can be defined by an upper region 1312 closer to the boundary with the second region 132 and by a lower region 1311 away from the boundary with the second region 132, in which the upper region 1312 is p-type having a composition inclination, and the lower region 1311 is p-type with no composition inclination.

For example, the Mg concentration at the boundary between the upper region 1312 and the lower region 1311 is 1×10¹⁷ cm⁻³. While the Mg concentration in the lower region 1311 is constant in the depth direction, the Mg concentration in the upper region 1312 continuously increases toward the boundary with the second region 132. The Mg concentration in the first region 131 is highest at the boundary between the upper region 1312 and the second region 132. The Mg concentration at the boundary is 5×10¹⁷ cm⁻³.

The second region 132 has the higher Mg concentration than the upper region 1312 of the first region 131, although both are the same p-type. In addition, the second region 132 has a larger degree of the composition inclination than the upper region 1312. The concentration gradient (inclination) of Mg in the depth direction is thus greater in the second region 132 than in the first region 131. The Mg concentration increases more steeply in the second region 132 than in the first region 131. The other configurations are the same as those in Configuration Example 1.

The vertical MOSFET 1G (Configuration Example 3) has the Al concentration distribution similar to that in the vertical MOSFET 1E (Configuration Example 1), so as to provide the three-dimensional channel in the second region 132. This configuration can achieve the vertical MOSFET with low ON-resistance while having high channel mobility. Further, Configuration Example 3 also provides the channel in the second region 132 separately from the top surface 10a, as in the case of Configuration Example 1. This can prevent the threshold voltage from excessively increasing or the channel mobility from excessively decreasing regardless of whether the surface Mg concentration in the second region 132 increases in order to deal with hole trapping. This configuration example thus can achieve both low hole trapping and high mobility.

### IV. Manufacturing Method 1

Next, Manufacturing method 1 for the vertical MOSFET according to the embodiment of the present disclosure is described below.

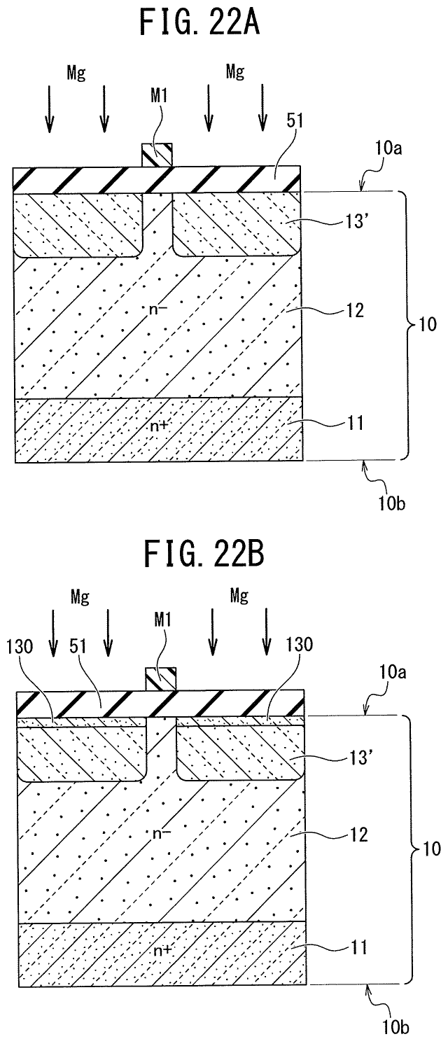

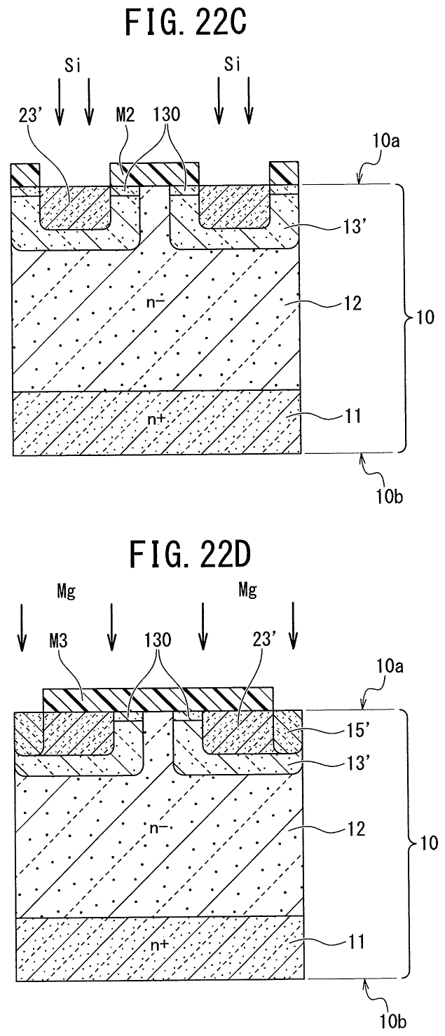

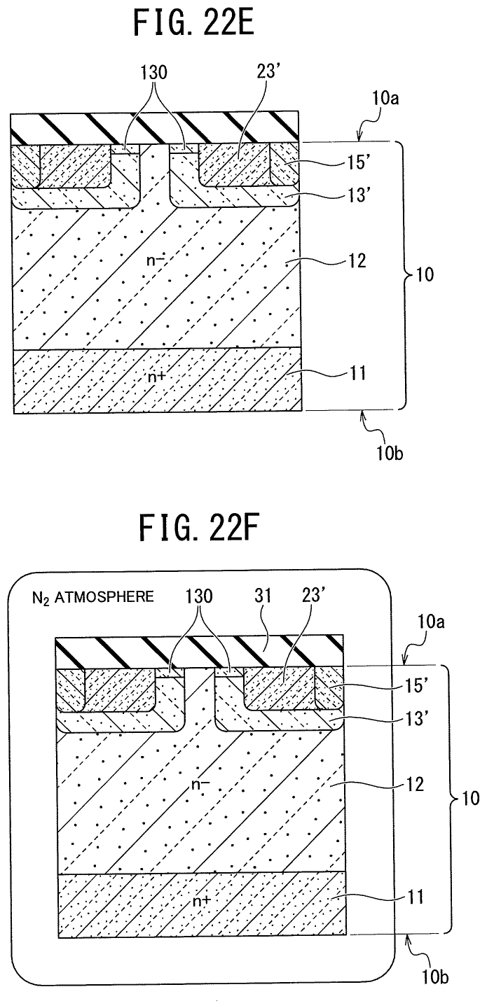

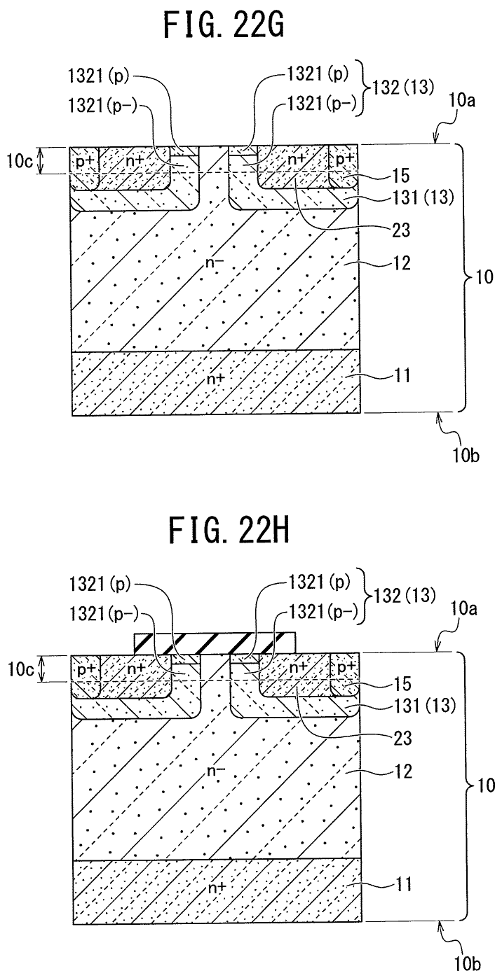

FIG. 22A to FIG. 22H are cross-sectional views sequentially illustrating Manufacturing method 1 for the vertical MOSFET according to Embodiment 6 of the present disclosure. As illustrated in FIG. 22A, the manufacturing apparatus forms a through-film 51 on the top surface 10a of the GaN substrate 10. The through-film 51 is a SiO₂ film, for example. This method deposits the through-film 51 that has a predetermined thickness so that an implantation peak of Mg is located on the top surface 10a of the GaN substrate 10 and the adjacent region in a step of ion implantation of Mg at a high concentration illustrated in FIG. 22B as described below. In particular, the through-film 51 is deposited to have a predetermined thickness so that the Mg concentration is highest on the top surface 10a of the GaN substrate 10 and the adjacent region.

For example, a relation between the thickness of the through-film 51, the implantation energy (acceleration voltage) of Mg, and the Mg concentration distribution (profile) in the GaN substrate 10 in the depth direction is preliminarily examined through experiments or simulations. The thickness of the through-film 51 is then obtained in accordance with the examined relation such that the implantation peak of Mg is located on the top surface 10a of the GaN substrate 10 and the adjacent region upon the ion implantation of Mg via the through-film 51 at the predetermined implantation energy. The through-film 51 illustrated in FIG. 22A is deposited so as to have such a thickness. The method of depositing the through-film 51 can be determined as appropriate, and is a CVD method, for example.

Before the high-concentration ion implantation of Mg, the manufacturing apparatus implants Mg ions as p-type impurities at a low concentration into the well-formation region 13′ of the GaN substrate 10, as illustrated in FIG. 22A. For example, the manufacturing apparatus forms the mask M1 on the through-film 51, and implants Mg ions at a low concentration into the GaN substrate 10 provided with the mask M1 via the through-film 51. The step of the low-concentration ion implantation of Mg illustrated in FIG. 22A sets the implantation energy (the acceleration voltage) and the dose of Mg so that the Mg concentration in the well-formation region 13′ is 1×10¹⁷ cm⁻³. The low-concentration ion implantation step may be either single-step ion implantation in which the accelerating energy has a single condition or multiple-step ion implantation in which the accelerating energy has plural conditions.

Next, as illustrated in FIG. 22B, the manufacturing apparatus heavily implants Mg ions as p-type impurities into the top surface 10a of the well-formation region 13′ and the adjacent region while still using the mask M1 so as to form a Mg high-concentration layer 130 on the top surface 10a and the adjacent region.

For example, as indicated by the Mg distribution II in the graph shown in FIG. 20, Mg ions are implanted at least into the second region 132 such that the maximum value of the Mg concentration in the second region 132 is greater than the maximum value of the Mg concentration in the first region 131, and the Mg concentration increases in the stepwise state from the first region 131 side toward the top surface 10a in contact with the gate insulating film 21 so as to be highest on the top surface 10a. Mg ions are implanted at least into the second region 132 preferably such that the Mg concentration on the top surface 10 is in a range of 5×10¹⁸ cm⁻³ or higher and 5×10¹⁹ cm⁻³ or lower.

As an example, the implantation energy and the dose of Mg are set such that the Mg concentration on the top surface 10a of the second region 132 and the adjacent region (the upper region 1322) is 1×10¹⁹ cm⁻³ and the Mg concentration under this region (in the lower region 1321 and the first region 131) is 1×10¹⁷ cm⁻³.

The high-concentration ion implantation step may be either single-step ion implantation or multiple-step ion implantation. The present embodiment can use either the single-step ion implantation or the multiple-step ion implantation appropriately depending on the thickness of the Mg high-concentration layer 130. The manufacturing apparatus sequentially removes the mask M1 and the through-film 51 after the high-concentration ion implantation of Mg.

Next, as illustrated in FIG. 22C, the manufacturing apparatus implants Si ions as n-type impurities into the source-formation region 23′ of the GaN substrate 10. For example, the manufacturing apparatus forms the mask M2 on the GaN substrate 10, and implants Si ions into the GaN substrate 10 provided with the mask M2. The manufacturing apparatus removes the mask M2 from the upper side of the GaN substrate 10 after the ion implantation. The step of ion implantation of Si illustrated in FIG. 22C sets the implantation energy and the dose of Si so as to lead the Si concentration in the source-formation region 23′ to be 3×10¹⁹ cm⁻³.

Next, as illustrated in FIG. 22D, the manufacturing apparatus implants Mg ions as p-type impurities into the contact-formation region 15′ of the GaN substrate 10. For example, the manufacturing apparatus forms the mask M3 on the top surface 10a of the GaN substrate 10, and implants Mg ions into the GaN substrate 10 provided with the mask M3. The manufacturing apparatus removes the mask M3 from the upper side of the GaN substrate 10 after the ion implantation. The step of ion implantation of Mg illustrated in FIG. 22D sets the implantation energy and the dose of Mg so as to lead the Mg concentration in the contact-formation region 15′ to be 1×10¹⁹ cm⁻³.

Next, as illustrated in FIG. 22E, the manufacturing apparatus deposits a nitride film including Al, such as the AlN film 31, on the top surface 10a of the GaN substrate 10. The thickness of the AlN film 31 is in a range of 100 nanometers or greater and 500 nanometers or less, for example.

Next, as illustrated in FIG. 22F, the manufacturing apparatus subjects the AlN film 31 and the GaN substrate 10 covered with the AlN film 31 to annealing. The annealing is rapid thermal annealing, for example. The annealing is executed under the conditions of a maximum temperature in a range of 1000° C. or higher and 1500° C. or lower, an annealing time at the maximum temperature in a range of 1 minute or longer and 60 minutes or shorter, and an atmosphere of N₂, for example. The execution of the annealing activates Mg and Si introduced to the GaN substrate 10, so as to form the well region 13, the n⁺-type source region 23, and the pt-type contact region 15 and further define the drift region 121, as illustrated in FIG. 22G.

The execution of the annealing also diffuses Al included in the AlN film 31 toward the top surface 10a of the GaN substrate 10 and the adjacent region 10c, which is within 50 nanometers from the top surface 10a in the depth direction, and preferably within 5 nanometers from the top surface 10a in the depth direction, for example. This diffusion provides the well region 13 with the first region 131 without Al doped and the second region 132 with Al doped. The second region 132 is a region of AlGaN, which is GaN with Al doped.

The Al concentration distribution in the second region 132 is the same as shown in FIG. 4, for example. The Al concentration is highest on the top surface 10a of the second region 132, and decreases in a continuous or stepwise state from the top surface 10a toward the first region 131. The Al concentration on the top surface of the second region 132 is in a range of 10 at % or higher and 30 at % or lower, for example.

This annealing also activates Mg included in the Mg high-concentration layer 130. The part of the second region 132 overlapping with the Mg high-concentration layer 130 is thus led to be p-type. The Mg concentration distribution in the second region 132 is the same as in Configuration Example 2 shown in FIG. 20, for example. The manufacturing apparatus then removes the AlN film 31 from the upper side of the GaN substrate 10 after the annealing.

Next, as illustrated in FIG. 22H, the manufacturing apparatus forms the gate insulating film 21 on the top surface 10a of the GaN substrate 10. For example, a SiO₂ film is deposited as the gate insulating film 21 so as to have a thickness of 100 nanometers. Next, the manufacturing apparatus forms the gate electrode 22 (refer to FIG. 20) and the source electrode 25 (refer to FIG. 20). The manufacturing apparatus also forms the drain electrode 26 (refer to FIG. 20) on the bottom surface 10b side of the GaN substrate 10. The vertical MOSFET IF (Configuration Example 2) as illustrated in FIG. 20 is thus completed through the process described above.

### V. Manufacturing Method 2

The step of the high-concentration ion implantation of Mg illustrated in FIG. 22B may implants Mg ions so that the Mg concentration continuously increases from the lower side of the well-formation region 13′ toward the top surface 10a, in other words, the Mg concentration gradually decreases from the top surface 10a in the depth direction. For example, as indicated by the Mg distribution I in the graph shown in FIG. 19, Mg ions may be implanted into the second region 132 so that the Mg concentration continuously increases from the boundary between the first region 131 and the second region 132 toward the top surface 10a. This can provide the vertical MOSFET 1E (Configuration Example 1) as illustrated in FIG. 19, for example.

Alternatively, as indicated by the Mg distribution III in the graph shown in FIG. 21, Mg ions may be implanted into the second region 132 and the first region 131 so that the Mg concentration continuously increases from the first region 131 toward the top surface 10a. The ion implantation of Mg into the second region 132 and the first region 131 may be executed such that the Mg concentration increases more steeply in the second region 132 than in the first region 131. This can provide the vertical MOSFET 1G (Configuration Example 3) as illustrated in FIG. 21, for example.

### VI. Manufacturing Method 3

The step of the high-concentration ion implantation of Mg illustrated in FIG. 22A may implants Mg ions into the GaN substrate 10 without use of the mask M1. In particular, Mg ions may be heavily implanted into the GaN substrate 10 including the JFET region located between one well region 13 and another well region 13 adjacent to each other in the horizontal direction (in the X-axis direction, for example). The method of manufacturing the vertical MOSFET in which Mg ions are heavily introduced including the JFET region is described in detail below.

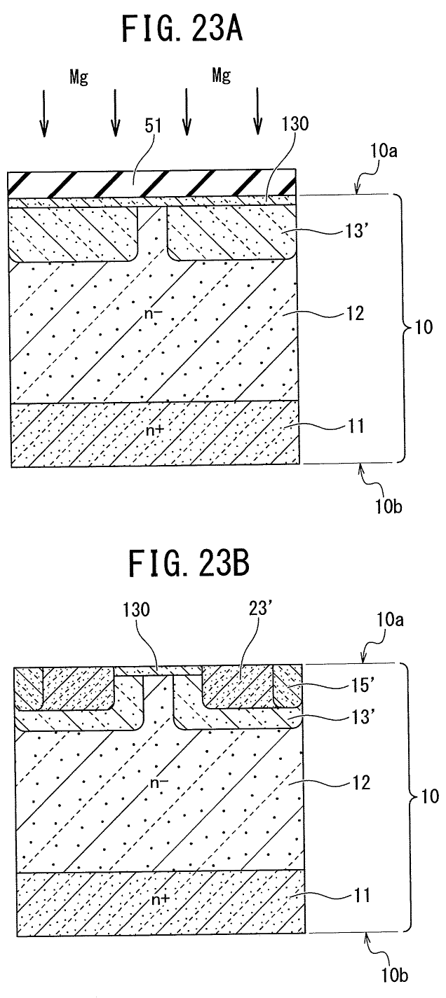

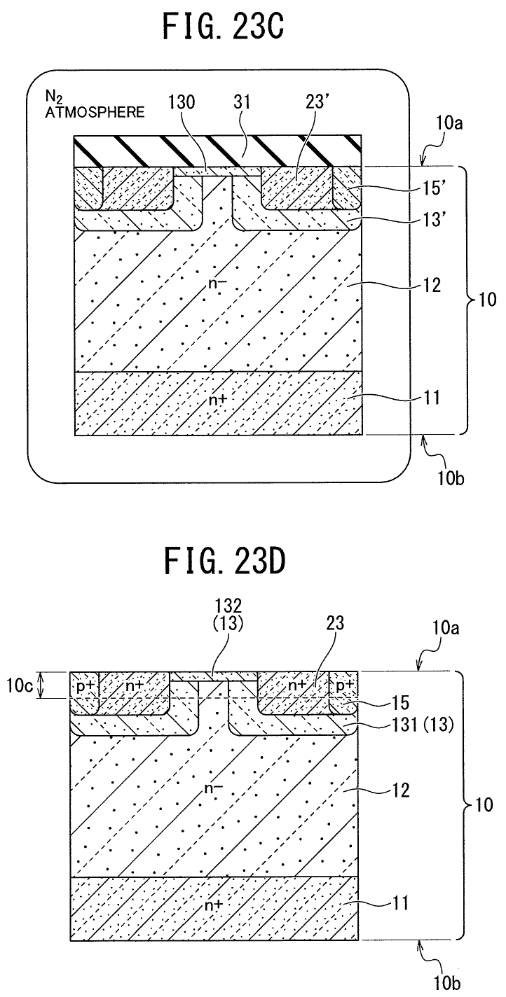

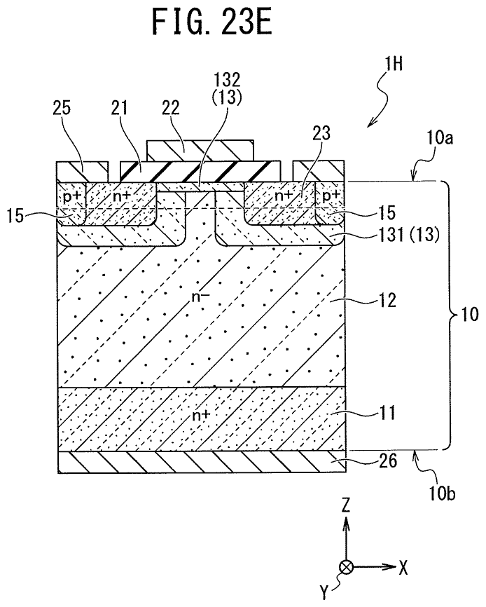

FIG. 23A to FIG. 23E are cross-sectional views sequentially illustrating Manufacturing method 3 for the vertical MOSFET according to Embodiment 6 of the present disclosure. Manufacturing method 3 includes the same steps as Manufacturing method 1 until the step of forming the through-film 51 on the top surface 10a of the GaN substrate 10 and implanting Mg ions at a low concentration into the well-formation region 13′ via the through-film 51, as illustrated in FIG. 23A. Manufacturing method 3 removes the mask M1 after the ion implantation of Mg at the low concentration.

Manufacturing method 3 heavily implants Mg ions into the top surface 10a of the GaN substrate 10 and the adjacent region after the removal of the mask M1 so as to form the Mg high-concentration layer 130 on the top surface 10a and the adjacent region. This method implants Mg ions at the high concentration into the GaN substrate 10 including the JFET region. For example, this method implants Mg ions at the high-concentration including the JFET region so as to have the Mg distribution II shown in the graph in FIG. 20.

The following steps are the same as those in Manufacturing Method 1. In particular, as illustrated in FIG. 23B, the manufacturing apparatus implants Si ions as n-type impurities into the source-formation region 23′ of the GaN substrate 10. Next, the manufacturing apparatus implants Mg ions as p-type impurities into the contact-formation region 15′ of the GaN substrate 10.

Next, as illustrated in FIG. 23C, the manufacturing apparatus deposits a nitride film including Al, such as the AlN film 31, on the top surface 10a of the GaN substrate 10. Next, the manufacturing apparatus subjects the AlN film 31 and the GaN substrate 10 covered with the AlN film 31 to annealing. The execution of the annealing activates Mg and Si introduced to the GaN substrate 10, so as to form the well region 13, the n⁺-type source region 23, and the p⁺-type contact region 15 and further define the drift region 121, as illustrated in FIG. 23D.

The execution of the annealing also diffuses Al included in the AlN film 31 toward the top surface 10a of the GaN substrate 10 and the adjacent region 10c, so as to provide the well region 13 with the first region 131 without Al doped and the second region 132 with Al doped.

This annealing further activates Mg included in the Mg high-concentration layer 130. The part of the second region 132 overlapping with the Mg high-concentration layer 130 is thus led to be p-type. The Mg concentration distribution in the second region 132 is the same as in Configuration Example 2 shown in FIG. 20, for example. The manufacturing apparatus then removes the AlN film 31 from the upper side of the GaN substrate 10 after the annealing.

Next, as illustrated in FIG. 23E, the manufacturing apparatus forms the gate insulating film 21 on the top surface 10a of the GaN substrate 10. Next, the manufacturing apparatus forms the gate electrode 22 and the source electrode 25. The manufacturing apparatus also forms the drain electrode 26 on the bottom surface 10b side of the GaN substrate 10. The vertical MOSFET 1H provided with the p-type second region 132 also in the JFET region is thus completed through the process described above. The configuration of the vertical MOSFET 1H can achieve a reduction in hole trapping in the JFET region, and further suppress a variation in the threshold voltage.

### VII. Modified Examples

### VII. i. Modified Example 1

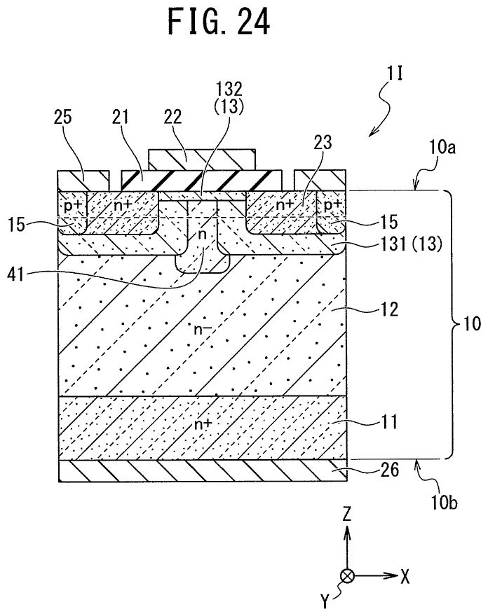

FIG. 24 is a cross-sectional view illustrating a configuration example (a modified example) of a vertical MOSFET 1I according to Embodiment 6 of the present disclosure. As illustrated in FIG. 24, Manufacturing method 3 described above may implant n-type impurity ions (such as Si) into the JFET region before the execution of the annealing illustrated in FIG. 23C, for example, before the formation of the AlN film 31. This example can form an n-type layer, such as the n-type JFET region 41, under the region to which Mg ions are heavily introduced (such as the p-type second region 132), as illustrated in FIG. 24. The vertical MOSFET 1I, which includes the n-type JFET region 41, can reduce the ON-resistance.

The manufacturing process for the vertical MOSFET II according to this modified example implants the n-type impurity ions into the JFET region. This ion implantation subjects the region under the top surface 10a of the p-type second region 132 and the adjacent region to n-type counter doping. The Mg concentration distribution in the JFET region is thus not limited to the Mg distribution II shown in FIG. 20, and may be led to the Mg distribution I shown in FIG. 19 or the Mg distribution III shown in FIG. 21. As indicated by the respective Mg distributions II and III, the counter doping described above can ensure a current path at a low resistance regardless of whether Mg ions are introduced into a relatively deep part in the JFET region away from the top surface 10a.

### VII. ii. Modified Example 2

Manufacturing methods 1 to 3 are illustrated above with the case of heavily implanting Mg ions via the through-film 51 so as to have the Mg concentration in the second region 132 that is highest on the surface in contact with the gate insulating film 21, namely, on the top surface 10a. The means for adjusting the surface concentration is not limited to the case described above. For example, the present disclosure may be applied to a method of heavily implanting Mg ions and then grinding the top surface 10a of the GaN substrate 10 by etch back or CMP, for example, so as to lead the implantation peak of Mg to be located on the top surface 10a. Alternatively, the high-concentration ion implantation of Mg via the through-film 51 and the etch back or grinding described above may be combined together. Such a method can also achieve the respective Mg distributions I to III as shown in FIG. 19 to FIG. 21.

### OTHER EMBODIMENTS

While the present disclosure has been described above by reference to Embodiments 1 to 6 and modified examples, it should be understood that the present disclosure is not intended to limit the descriptions and the drawings composing part of this disclosure. Various alternative embodiments and modified examples will be apparent to those skilled in the art according to this disclosure. For example, the respective embodiments 1 to 5 are illustrated above with the case in which the electrode in contact with the contact region 15 is the source electrode 25, but the present disclosure is not limited to this case. The contact region 15 may be in contact with any other electrode. It should be understood that the present disclosure can include various embodiments not disclosed herein, and can include at least any of omissions, replacements, or modifications of the constitutional elements without departing from the teaching of the respective embodiments and modified examples described above. It should also be understood that the effects described herein are illustrated merely as some examples that are not limited to the above descriptions, and the present disclosure may have other effects not disclosed herein.

The present disclosure can also have the following configurations.
(1) A nitride semiconductor device comprising:
   a nitride semiconductor layer of a first conductivity-type;
   a well region of a second conductivity-type provided in the nitride semiconductor layer; and
   a gate insulating film provided on a first surface side of the nitride semiconductor layer so as to cover the well region,
   wherein the well region includes
      a first region to which Al is not doped, and
      a second region to which Al is doped, the second region being provided on the first region,
   the second region having an Al concentration distribution in which an Al concentration is highest on a first surface in contact with the gate insulating film and decreases in a continuous or stepwise state from the first surface toward the first region.
(2) The nitride semiconductor device of the above (1), wherein:
   the first conductivity-type is n-type, and the second conductivity-type is p-type; and
   the first region and the second region both include p-type impurities of Mg.
(3) The nitride semiconductor device of the above (2), wherein a maximum value of a Mg concentration in the second region is greater than a maximum value of a Mg concentration in the first region.
(4) The nitride semiconductor device of the above (3), wherein the second region has a Mg concentration distribution in which the Mg concentration increases in a continuous or stepwise state from the first region side toward the first surface in contact with the gate insulating film.
(5) The nitride semiconductor device of the above (3) or (4), wherein the Mg concentration in the second region is highest on the first surface in contact with the gate insulating film.
(6) The nitride semiconductor device of the above (3) or (4), wherein the Mg concentration on the first surface in contact with the gate insulating film in the second region is in a range of 5×10¹⁸ cm⁻³ or higher and 5×10¹⁹ cm⁻³ or lower.
(7) The nitride semiconductor device of any one of the above (1) to (6), wherein the first region and the second region are stacked together on a nonpolar surface of the nitride semiconductor layer.
(8) The nitride semiconductor device of any one of the above (1) to (6), wherein the first region and the second region are stacked together on a polar surface of the nitride semiconductor layer.
(9) The nitride semiconductor device of any one of the above (1) to (8), wherein the second region has a thickness of 50 nanometers or smaller.
(10) The nitride semiconductor device of any one of the above (1) to (8), wherein the second region has a thickness of 5 nanometers or smaller.
(11) The nitride semiconductor device of any one of the above (1) to (10), further comprising:
   a drift region of the first conductivity-type provided in the nitride semiconductor layer and located between a second surface opposite to the first surface of the nitride semiconductor layer and the well region; and
   a nitride semiconductor substrate of the first conductivity-type provided on the second surface side of the nitride semiconductor layer so as to be in contact with the drift region.
(12) The nitride semiconductor device of the above (11), further comprising:
   a plurality of the well regions; and
   a high-concentration region of the first conductivity-type provided in the nitride semiconductor layer so as to be located between one of the well regions and another well region next to each other,
   wherein the high-concentration region has a higher impurity concentration of the first conductivity-type than the drift region.
(13) The nitride semiconductor device of the above (11) or (12), further comprising:
   a gate electrode provided on the first surface side of the nitride semiconductor layer so as to be opposed to the well region with the gate insulating film interposed;
   a source region of the first conductivity-type provided in the nitride semiconductor layer so as to be in contact with the well region;
   a source electrode provided on the first surface side of the nitride semiconductor layer so as to be in contact with the source region; and
   a drain electrode provided on another side of the nitride semiconductor layer with the nitride semiconductor substrate interposed so as to be connected to the drift region via the nitride semiconductor substrate.
(14) The nitride semiconductor device of the above (13), further comprising a trench provided in the nitride semiconductor layer,
   wherein the gate electrode is provided inside the trench via the gate insulating film.
(15) The nitride semiconductor device of any one of the above (11) to (14), wherein the drift region includes a pillar of the second conductivity-type provided to extend from a bottom of the well region toward the second surface.
(16) The nitride semiconductor device of any one of the above (1) to (15), wherein Al doped to the second region is present mainly as a nitride.
(17) The nitride semiconductor device of any one of the above (1) to (16), wherein the gate insulating film includes at least either a Si oxide or an Al oxide.
(18) The nitride semiconductor device of any one of the above (1) to (16), wherein:
   the gate insulating film includes a Si oxynitride film and at least either an Si oxide or an Al oxide; and
   the Si oxynitride film and at least either the Si oxide or the Al oxide are stacked sequentially from the first surface side of the nitride semiconductor layer.
(19) The nitride semiconductor device of any one of the above (1) to (18), wherein the second region is provided with a channel of a MOSFET.
(20) A method of manufacturing a nitride semiconductor device, comprising:
   forming a well region of a second conductivity-type on a first surface side of a nitride semiconductor layer of a first conductivity-type; and
   forming a gate insulating film on the first surface side of the nitride semiconductor layer so as to cover the well region,
   wherein
   the forming the well region includes
      forming a first region to which Al is not doped, and
      forming, on the first region, a second region to which Al is doped, and
   the forming the second region is executed so as to form an Al concentration distribution in the second region in which an Al concentration is highest on a first surface in contact with the gate insulating film and decreases in a continuous or stepwise state from the first surface toward the first region.
(21) The method of manufacturing the nitride semiconductor device of the above (20), wherein:
   the first conductivity-type is n-type, and the second conductivity-type is p-type; and
   the forming the well region implants Mg ions as p-type impurities into the first surface of the nitride semiconductor layer or epitaxially grows a nitride semiconductor including Mg as the p-type impurities on the first surface so as to introduce Mg into the first region and the second region.
(22) The method of manufacturing the nitride semiconductor device of the above (21), wherein the forming the well region implants Mg ions at least into the second region so that a maximum value of a Mg concentration in the second region is greater than a maximum value of a Mg concentration in the first region.
(23) The method of manufacturing the nitride semiconductor device of the above (22), wherein the forming the well region implants Mg ions at least into the second region so that the Mg concentration increases in a continuous or stepwise state from the first region side toward the first surface in contact with the gate insulating film.
(24) The method of manufacturing the nitride semiconductor device of the above (22) or (23), wherein the forming the well region implants Mg ions at least into the second region so that the Mg concentration in the second region is highest on the first surface in contact with the gate insulating film.
(25) The method of manufacturing the nitride semiconductor device of the above (22) or (23), wherein the forming the well region implants Mg ions at least into the second region so that the Mg concentration on the first surface in contact with the gate insulating film in the second region is in a range of 5×10¹⁸ cm⁻³ or higher and 5×10¹⁹ cm⁻³ or lower.
(26) The method of manufacturing the nitride semiconductor device of any one of the above (20) to (25), wherein the forming the second region deposits a nitride film including Al on the first surface of the nitride semiconductor layer, and subjects the nitride film and the nitride semiconductor layer covered with the nitride film to annealing so as to provide the Al concentration distribution in the second region.
(27) The method of manufacturing the nitride semiconductor device of any one of the above (20) to (25), wherein the forming the second region implants Al ions into the first surface side of the nitride semiconductor layer and subjects the nitride semiconductor layer to which Al ions are implanted to annealing so as to provide the Al concentration distribution in the second region.
(28) The method of manufacturing the nitride semiconductor device of any one of the above (20) to (25), wherein the forming the second region epitaxially grows the second region having the Al concentration distribution on the first region.

What is claimed is:

1. A nitride semiconductor device comprising:
a nitride semiconductor layer of a first conductivity-type;
a well region of a second conductivity-type provided in the nitride semiconductor layer; and
a gate insulating film provided on a first surface side of the nitride semiconductor layer so as to cover the well region,
wherein the well region includes
a first region to which Al is not doped, and
a second region to which Al is doped, the second region being provided on the first region,
the second region having an Al concentration distribution in which an Al concentration is highest on a first surface in contact with the gate insulating film and decreases in a continuous or stepwise state from the first surface toward the first region.

2. The nitride semiconductor device of claim 1, wherein:
the first conductivity-type is n-type, and the second conductivity-type is p-type; and
the first region and the second region both include p-type impurities of Mg.

3. The nitride semiconductor device of claim 2, wherein a maximum value of a Mg concentration in the second region is greater than a maximum value of a Mg concentration in the first region.

4. The nitride semiconductor device of claim 3, wherein the second region has a Mg concentration distribution in which the Mg concentration increases in a continuous or stepwise state from the first region toward the first surface in contact with the gate insulating film.

5. The nitride semiconductor device of claim 3, wherein the Mg concentration in the second region is highest on the first surface in contact with the gate insulating film.

6. The nitride semiconductor device of claim 3, wherein the Mg concentration on the first surface in contact with the gate insulating film in the second region is in a range of 5×10¹⁸ cm⁻³ or higher and 5×10¹⁹ cm⁻³ or lower.

7. The nitride semiconductor device of claim 1, wherein the first region and the second region are stacked together on a nonpolar surface of the nitride semiconductor layer.

8. The nitride semiconductor device of claim 1, wherein the first region and the second region are stacked together on a polar surface of the nitride semiconductor layer.

9. The nitride semiconductor device of claim 1, wherein the second region has a thickness of 50 nanometers or smaller.

10. The nitride semiconductor device of claim 1, wherein the second region has a thickness of 5 nanometers or smaller.

11. The nitride semiconductor device of claim 1, further comprising:
a drift region of the first conductivity-type provided in the nitride semiconductor layer and located between a second surface opposite to the first surface of the nitride semiconductor layer and the well region; and
a nitride semiconductor substrate of the first conductivity-type provided on the second surface side of the nitride semiconductor layer so as to be in contact with the drift region.

12. The nitride semiconductor device of claim 11, further comprising:
a plurality of the well regions; and
a high-concentration region of the first conductivity-type provided in the nitride semiconductor layer so as to be located between one of the well regions and another well region next to each other,
wherein the high-concentration region has a higher impurity concentration of the first conductivity-type than the drift region.

13. The nitride semiconductor device of claim 11, further comprising:
a gate electrode provided on the first surface side of the nitride semiconductor layer so as to be opposed to the well region with the gate insulating film interposed;
a source region of the first conductivity-type provided in the nitride semiconductor layer so as to be in contact with the well region;
a source electrode provided on the first surface side of the nitride semiconductor layer so as to be in contact with the source region; and
a drain electrode provided on another side of the nitride semiconductor layer with the nitride semiconductor substrate interposed so as to be connected to the drift region via the nitride semiconductor substrate.

14. The nitride semiconductor device of claim 13, further comprising a trench provided in the nitride semiconductor layer,
wherein the gate electrode is provided inside the trench via the gate insulating film.

15. The nitride semiconductor device of claim 11, wherein the drift region includes a pillar of the second conductivity-type provided to extend from a bottom of the well region toward the second surface.

16. The nitride semiconductor device of claim 1, wherein Al doped to the second region is present mainly as a nitride.

17. The nitride semiconductor device of claim 1, wherein the gate insulating film includes at least either a Si oxide or an Al oxide.

18. The nitride semiconductor device of claim 1, wherein:
the gate insulating film includes a Si oxynitride film and at least either an Si oxide or an Al oxide; and
the Si oxynitride film and at least either the Si oxide or the Al oxide are stacked sequentially from the first surface of the nitride semiconductor layer.

19. The nitride semiconductor device of claim 1, wherein the second region is provided with a channel of a MOSFET.
